(19) United States
(12) Patent Application Publication
(10) Pub. No.: US 2025/0294925 A1
(43) Pub. Date: Sep. 18, 2025

(54) EPITAXIAL DIE FOR SEMICONDUCTOR LIGHT-EMITTING DEVICE, SEMICONDUCTOR LIGHT-EMITTING DEVICE INCLUDING SAME, AND MANUFACTURING METHODS THEREOF

(71) Applicant: WAVELORD CO., LTD, Hwaseong-si (KR)

(72) Inventors: Juneo SONG, Suwon-si (KR); Hyeong Seon YUN, Paju-si (KR); Young Hun HAN, Osan-si (KR); Ji Hyung MOON, Gunpo-si (KR)

(73) Assignee: WAVELORD CO., LTD, Hwaseong-si (KR)

(21) Appl. No.: 18/860,629

(22) PCT Filed: Sep. 18, 2023
(86) PCT No.: PCT/KR2023/014066

§ 371 Date: Oct. 26, 2024

(30) Foreign Application Priority Data
Sep. 19, 2022 (KR) 10-2022-0117788
Nov. 23, 2022 (KR) 10-2022-0158160
Dec. 5, 2022 (KR) 10-2022-0167977

(51) Int. Cl. H10H 20/831; H10H 20/84

(52) U.S. Cl. CPC H10H 20/831; H10H 20/84

(57) ABSTRACT

The present invention relates to an epitaxial die for a semiconductor light-emitting device emitting blue light or green light, a semiconductor light-emitting device including same, and manufacturing methods thereof, wherein in the epitaxial die only one of two electrodes is exposed to the outside, and a process of forming an ohmic contact electrode can be completed in an epitaxial die manufacturing step.

### TECHNICAL FIELD

The present invention relates to an epitaxial die for a semiconductor light-emitting device and a semiconductor light-emitting device including the same.

### BACKGROUND ART

In general, micro light-emitting diode (LED) displays (including mini LED displays) can be classified into micro LED displays with a passive matrix (PM) driving method and micro LED displays with an active matrix (AM) driving method.

Here, PM-driven micro LED displays typically have a sapphire support substrate, which finally remains, and use sorted thick BGR (Blue, Green, and Red) chips (with both fully fabricated positive electrode and negative electrode of the LED), which are transferred using a chip die-level process in which either horizontal chips or flip chips can be generally utilized.

In addition, AM-driven micro LED displays typically do not have a sapphire support substrate, which finally remains, and use unsorted thin BGR (Blue, Green, and Red) chips, which are transferred using a wafer-level process in which horizontal chips, flip chips, or vertical chips can all be generally utilized.

These conventional typical PM- and AM-driven micro LED displays have the following common issues.

First, when considering the application of vertical chips to reduce chip die size, there is a problem that, unlike flip chips, which allow defects to be immediately confirmed after bonding, in the case of vertical chips, defects can only be confirmed after bonding and subsequent top-level wiring.

Further, in terms of a bonding process, higher precision is required in the bonding process due to the reduction in chip die size, and improved bonding strength is required due to the reduction in bonding area.

Further, in terms of a tiling process in which a plurality of unit displays are combined like tiles, there is an issue in which boundaries between the unit displays become distinct when the displays are turned off or show a black screen, and this is more noticeable in the PM driving method compared to the AM driving method. In addition, although many aspects have been improved, there is still an issue in which boundaries are visible on monochromatic screens and still images, and when using thin-film transistor (TFT) glass panels for tiling, the process is challenging due to the risk of glass breakage. Furthermore, due to the tolerance relationship between pixel pitch and tiling boundaries, various issues exist, including the expectation that the tiling process will be difficult to apply to products smaller than 100 inches.

Meanwhile, in the conventional PM-driven micro LED displays, the reduction in chip die size is the greatest challenge. That is, from an aspect ratio perspective, achieving a reduction in chip die size essentially requires decreasing a thickness of a sapphire final support substrate, but the current limit for the thickness of the sapphire final support substrate is about 80 μm to 70 μm, and when reducing the thickness below 50 μm, a substrate breaking issue occurs. Further, there are complex issues related to chip measurement and classification in this type of micro LED display, and it is expected that flip chips will be mainly used in this type of display rather than horizontal and vertical chips, but when the flip chips are used, high-precision and high-speed bonding processes, as well as materials for them, are separately required.

Further, in conventional AM-driven micro LED displays, in which the final support substrate is not present and chip die size reduction is possible, there are issues related to resolving defects (No Good, NG). That is, the fundamental issues in epitaxial and fab processes, such as yield improvement related to wavelength and electrical characteristics at the chip-on-wafer (COW) level, have not been resolved, and there is difficulty in 100% sorting and removal of defective (NG) chips. In order to address these issues, approaches such as redundancy have been recently attempted, but have not provided a fundamental solution.

### DISCLOSURE

### Technical Problem

The present invention is directed to solving the above-mentioned conventional problems and providing an epitaxial die for a semiconductor light-emitting device that emits blue or green light, in which only one of two electrodes is exposed to the outside, and a process of forming a p-ohmic contact electrode or an n-ohmic contact electrode is completed at the operation of manufacturing the epitaxial die, thereby enabling a significant reduction in thickness and chip die size to improve light output, a semiconductor light-emitting device including the same, and a method of manufacturing the same.

### Technical Solution

According to the present invention, the above object is achieved by an epitaxial die for a semiconductor light-emitting device, including a growth substrate, a light-emitting part formed on the growth substrate, having a side portion etched to a predetermined depth, and configured to generate light, a first ohmic electrode formed on the light-emitting part and electrically connected to the light-emitting part, a second ohmic electrode formed on the etched side portion of the light-emitting part and electrically connected to the light-emitting part, a passivation layer covering a side portion of the first ohmic electrode from the etched side portion of the light-emitting part via the second ohmic electrode, and a bonding pad layer formed on the first ohmic electrode and the passivation layer to be electrically connected to the first ohmic electrode and functioning as a vertical chip bonding pad, wherein the second ohmic electrode is interposed between the passivation layer and the light-emitting part and is not exposed.

According to the present invention, the above object is achieved by an epitaxial die for a semiconductor light-emitting device, including a growth substrate, a light-emitting part formed on the growth substrate and configured to generate light, a first ohmic electrode formed on the light-emitting part and electrically connected to the light-emitting part, a passivation layer covering a side portion of the first ohmic electrode, and a bonding pad layer formed on the first ohmic electrode and the passivation layer to be electrically connected to the first ohmic electrode and functioning as a vertical chip bonding pad.

According to the present invention, the above object is achieved by a semiconductor light-emitting device including a substrate part on which a first electrode pad and a second electrode pad are each formed, an epitaxial die that includes a light-emitting part having a side portion etched to a predetermined depth and configured to generate light, a first ohmic electrode formed on the light-emitting part and electrically connected to the light-emitting part, a second ohmic electrode formed on the etched portion of the light-emitting part and electrically connected to the light-emitting part, a passivation layer covering a side portion of the first ohmic electrode from the etched portion of the light-emitting part via the second ohmic electrode, and a bonding pad layer formed on the first ohmic electrode and the passivation layer to be electrically connected to the first ohmic electrode and functioning as a vertical chip bonding pad, and is placed upside down on the first electrode pad, a bonding layer bonding and electrically connecting the first electrode pad and the bonding pad layer, an extension electrode electrically connecting the second electrode pad and the second ohmic electrode, and a mold part surrounding the epitaxial die and the extension electrode so that the light-emitting part and the extension electrode are exposed, wherein one side of the light-emitting part is etched so that the second ohmic electrode is exposed, and the extension electrode electrically connects the second electrode pad and the exposed second ohmic electrode.

According to the present invention, the above object is achieved by a semiconductor light-emitting device including a substrate part on which a first electrode pad and a second electrode pad are each formed, an epitaxial die that includes a light-emitting part configured to generate light, a first ohmic electrode formed on the light-emitting part and electrically connected to the light-emitting part, a passivation layer covering a side portion of the first ohmic electrode, and a bonding pad layer formed on the first ohmic electrode and the passivation layer to be electrically connected to the first ohmic electrode and functioning as a vertical chip bonding pad, and is placed upside down on the first electrode pad, a bonding layer bonding and electrically connecting the first electrode pad and the bonding pad layer, a second ohmic electrode formed to be exposed on an upper surface of the light-emitting part and electrically connected to the light-emitting part, an extension electrode electrically connecting the second electrode pad and the exposed second ohmic electrode, and a mold part surrounding the epitaxial die and the extension electrode so that the light-emitting part and the extension electrode are exposed.

According to the present invention, the above object is achieved by a method of manufacturing an epitaxial die for a semiconductor light-emitting device, including a first operation of preparing a growth substrate, a second operation of forming a light-emitting part on the growth substrate, a third operation of forming a first ohmic electrode on the light-emitting part, a fourth operation of etching a side portion of each of the light-emitting part and the first ohmic electrode to a predetermined depth, and forming a second ohmic electrode on the etched portion, a fifth operation of forming a passivation layer that covers the first ohmic electrode from the etched portion of the light-emitting part via the second ohmic electrode, and a sixth operation of etching a portion of the passivation layer to expose the first ohmic electrode and forming a bonding pad layer, which functions as a vertical chip bonding pad, to come into contact with the exposed first ohmic electrode.

According to the present invention, the above object is achieved by a method of manufacturing an epitaxial die for a semiconductor light-emitting device, including a first operation of preparing a growth substrate, a second operation of forming a light-emitting part on the growth substrate, a third operation of forming a first ohmic electrode on the light-emitting part, a fourth operation of forming a passivation layer that covers the first ohmic electrode, and a fifth operation of etching a portion of the passivation layer to expose the first ohmic electrode and forming a bonding pad layer, which functions as a vertical chip bonding pad, to come into contact with the exposed first ohmic electrode.

According to the present invention, the above object is achieved by a method of manufacturing a semiconductor light-emitting device, including a first operation of preparing an epitaxial die including a growth substrate, a light-emitting part formed on the growth substrate, having a side portion etched to a predetermined depth, and configured to generate light, a first ohmic electrode formed on the light-emitting part and electrically connected to the light-emitting part, a second ohmic electrode formed on the etched side portion of the light-emitting part and electrically connected to the light-emitting part, a passivation layer covering a side portion of the first ohmic electrode from the etched side portion of the light-emitting part via the second ohmic electrode, and a bonding pad layer formed on the first ohmic electrode and the passivation layer to be electrically connected to the first ohmic electrode and functioning as a vertical chip bonding pad, and preparing a substrate part on which a first electrode pad and a second electrode pad are each formed, a second operation of placing the epitaxial die upside down on the first electrode pad, and bonding and electrically connecting the first electrode pad and the bonding pad layer through a bonding layer, a third operation of separating the growth substrate, a fourth operation of forming a mold part that surrounds the epitaxial die so that the light-emitting part is exposed, a fifth operation of etching one side of the light-emitting part so that the second ohmic electrode is exposed, and a sixth operation of etching the mold part so that the second electrode pad is exposed, and forming an extension electrode that electrically connects the second electrode pad and the second ohmic electrode.

According to the present invention, the above object is achieved by a method of manufacturing a semiconductor light-emitting device, including a first operation of preparing an epitaxial die including a growth substrate, a light-emitting part formed on the growth substrate and configured to generate light, a first ohmic electrode formed on the light-emitting part and electrically connected to the light-emitting part, a passivation layer covering a side portion of the first ohmic electrode, and a bonding pad layer formed on the first ohmic electrode and the passivation layer to be electrically connected to the first ohmic electrode and functioning as a vertical chip bonding pad, and preparing a substrate part on which a first electrode pad and a second electrode pad are each formed, a second operation of placing the epitaxial die upside down on the first electrode pad, and bonding and electrically connecting the first electrode pad and the bonding pad layer through a bonding layer, a third operation of separating the growth substrate, a fourth operation of forming a mold part that surrounds the epitaxial die so that the light-emitting part is exposed, a fifth operation of forming a second ohmic electrode formed to be exposed on an upper surface of the light-emitting part and electrically connected to the light-emitting part, a sixth operation of etching the mold part so that the second electrode pad is exposed, and forming an extension electrode that electrically connects the second electrode pad and the second ohmic electrode.

According to the present invention, the above object is achieved by an epitaxial die for a semiconductor light-emitting device, including a growth substrate, a light-emitting part formed on the growth substrate, having one side etched to a predetermined depth, and configured to generate light, a first ohmic electrode formed on the light-emitting part and electrically connected to the light-emitting part, a second ohmic electrode formed on the etched portion on one side of the light-emitting part and electrically connected to the light-emitting part, a first passivation layer covering the first ohmic electrode and the second ohmic electrode and partially open to expose a portion of the first ohmic electrode, a contact electrode formed on the exposed first ohmic electrode and electrically connected to the first ohmic electrode, a second passivation layer covering the first passivation layer and the contact electrode, and a bonding pad layer formed on the second passivation layer to be electrically connected to the second ohmic electrode and functioning as a vertical chip bonding pad, wherein the contact electrode is interposed between the second passivation layer and the first ohmic electrode and is not exposed.

According to the present invention, the above object is achieved by an epitaxial die for a semiconductor light-emitting device, including a light-emitting part having one side etched to a predetermined depth and configured to generate light, a first ohmic electrode formed on the light-emitting part and electrically connected to the light-emitting part, a second ohmic electrode formed on the etched portion on one side of the light-emitting part and electrically connected to the light-emitting part, a contact electrode formed on the first ohmic electrode and electrically connected to the first ohmic electrode, a temporary bonding layer formed to cover the contact electrode, a temporary substrate placed on the temporary bonding layer, and a bonding pad layer formed to come into contact with a lower surface of the light-emitting part to be electrically connected to the second ohmic electrode and functioning as a vertical chip bonding pad, wherein the contact electrode is interposed between the temporary bonding layer and the first ohmic electrode and is not exposed.

According to the present invention, the above object is achieved by an epitaxial die for a semiconductor light-emitting device, including a light-emitting part configured to generate light, a first ohmic electrode formed on the light-emitting part and electrically connected to the light-emitting part, a contact electrode formed on the first ohmic electrode and electrically connected to the first ohmic electrode, a temporary bonding layer formed to cover the contact electrode, a temporary substrate bonded on the temporary bonding layer, and a bonding pad layer formed to come into contact with a lower surface of the light-emitting part to be electrically connected to the light-emitting part and functioning as a vertical chip bonding pad, wherein the contact electrode is interposed between the temporary bonding layer and the first ohmic electrode and is not exposed.

According to the present invention, the above object is achieved by a semiconductor light-emitting device including a substrate part on which a first electrode pad and a second electrode pad are each formed, an epitaxial die that includes a light-emitting part having one side etched to a predetermined depth and configured to generate light, a first ohmic electrode formed on the light-emitting part and electrically connected to the light-emitting part, a second ohmic electrode formed on the etched portion on one side of the light-emitting part and electrically connected to the light-emitting part, a first passivation layer covering the first ohmic electrode and the second ohmic electrode and partially open to expose a portion of the first ohmic electrode, a contact electrode formed on the exposed first ohmic electrode and electrically connected to the first ohmic electrode, a second passivation layer covering the first passivation layer and the contact electrode, and a bonding pad layer formed on the second passivation layer to be electrically connected to the second ohmic electrode and functioning as a vertical chip bonding pad, and is placed upside down on the first electrode pad, a bonding layer bonding and electrically connecting the first electrode pad and the bonding pad layer, an extension electrode electrically connecting the second electrode pad and the exposed contact electrode, and a mold part surrounding the epitaxial die and the extension electrode.

According to the present invention, the above object is achieved by a semiconductor light-emitting device including a substrate part on which a first electrode pad and a second electrode pad are each formed, an epitaxial die that includes a light-emitting part having one side etched to a predetermined depth and configured to generate light, a first ohmic electrode formed on the light-emitting part and electrically connected to the light-emitting part, a second ohmic electrode formed on the etched portion on one side of the light-emitting part and electrically connected to the light-emitting part, a contact electrode formed on the first ohmic electrode and electrically connected to the first ohmic electrode, and a bonding pad layer formed to come into contact with a lower surface of the light-emitting part to be electrically connected to the second ohmic electrode and functioning as a vertical chip bonding pad, and is placed on the first electrode pad, a bonding layer bonding and electrically connecting the first electrode pad and the bonding pad layer, an extension electrode electrically connecting the second electrode pad and the contact electrode exposed to the outside, and a mold part surrounding the epitaxial die and the extension electrode.

According to the present invention, the above object is achieved by a semiconductor light-emitting device including a substrate part on which a first electrode pad and a second electrode pad are each formed, an epitaxial die that includes a light-emitting part configured to generate light, a first ohmic electrode formed on the light-emitting part and electrically connected to the light-emitting part, a contact electrode formed on the first ohmic electrode and electrically connected to the first ohmic electrode, and a bonding pad layer formed to come into contact with a lower surface of the light-emitting part to be electrically connected to the light-emitting part and functioning as a vertical chip bonding pad, and is placed on the first electrode pad, a bonding layer bonding and electrically connecting the first electrode pad and the bonding pad layer, an extension electrode electrically connecting the second electrode pad and the contact electrode exposed to the outside, and a mold part surrounding the epitaxial die and the extension electrode.

According to the present invention, the above object is achieved by a method of manufacturing an epitaxial die for a semiconductor light-emitting device, including a first operation of preparing a growth substrate, a second operation of forming a light-emitting part on the growth substrate, a third operation of forming a first ohmic electrode on the light-emitting part, a fourth operation of etching one side of each of the light-emitting part and the first ohmic electrode to a predetermined depth, and forming a second ohmic electrode on the etched portion, a fifth operation of forming a first passivation layer that covers the first ohmic electrode and the second ohmic electrode, a sixth operation of etching a portion of the first passivation layer to expose the first ohmic electrode and forming a contact electrode to come into contact with the exposed first ohmic electrode, a seventh operation of forming a second passivation layer that covers the first passivation layer and the contact electrode, and an eighth operation of forming a bonding pad layer electrically connected to the second ohmic electrode and functioning as a vertical chip bonding pad on the second passivation layer.

According to the present invention, the above object is achieved by a method of manufacturing an epitaxial die for a semiconductor light-emitting device, including a first operation of preparing a growth substrate and a temporary substrate, a second operation of forming a light-emitting part on the growth substrate, a third operation of forming a first ohmic electrode on the light-emitting part, a fourth operation of etching one side of each of the light-emitting part and the first ohmic electrode to a predetermined depth, and forming a second ohmic electrode on the etched portion, a fifth operation of forming a passivation layer that covers the first ohmic electrode and the second ohmic electrode, a sixth operation of etching a portion of the passivation layer to expose the first ohmic electrode and forming a contact electrode to come into contact with the exposed first ohmic electrode, a seventh operation of bonding the temporary substrate and the passivation layer, in which the contact electrode is exposed, through a temporary bonding layer, an eighth operation of separating the growth substrate, and a ninth operation of forming a bonding pad layer formed on a lower surface of the light-emitting part to be electrically connected to the second ohmic electrode and functioning as a vertical chip bonding pad.

According to the present invention, the above object is achieved by a method of manufacturing an epitaxial die for a semiconductor light-emitting device, including a first operation of preparing a growth substrate and a temporary substrate, a second operation of forming a light-emitting part on the growth substrate, a third operation of forming a first ohmic electrode on the light-emitting part, a fourth operation of forming a passivation layer that covers the first ohmic electrode, a fifth operation of etching a portion of the passivation layer to expose the first ohmic electrode and forming a contact electrode to come into contact with the exposed first ohmic electrode, a sixth operation of bonding the temporary substrate and the passivation layer, in which the contact electrode is exposed, through a temporary bonding layer, a seventh operation of separating the growth substrate, and an eighth operation of forming a bonding pad layer formed on a lower surface of the light-emitting part to be electrically connected to the light-emitting part and functioning as a vertical chip bonding pad.

According to the present invention, the above object is achieved by a method of manufacturing a semiconductor light-emitting device, including a first operation of preparing an epitaxial die including a growth substrate, a light-emitting part formed on the growth substrate, having one side etched to a predetermined depth, and configured to generate light, a first ohmic electrode formed on the light-emitting part and electrically connected to the light-emitting part, a second ohmic electrode formed on the etched portion on one side of the light-emitting part and electrically connected to the light-emitting part, a first passivation layer covering the first ohmic electrode and the second ohmic electrode and partially open to expose a portion of the first ohmic electrode, a contact electrode formed on the exposed first ohmic electrode and electrically connected to the first ohmic electrode, a second passivation layer covering the first passivation layer and the contact electrode, and a bonding pad layer formed on the second passivation layer to be electrically connected to the second ohmic electrode and functioning as a vertical chip bonding pad, and preparing a substrate part on which a contact electrode pad and a second electrode pad are each formed, a second operation of placing the epitaxial die upside down on the first electrode pad, and bonding and electrically connecting the first electrode pad and the bonding pad layer through a bonding layer, a third operation of separating the growth substrate, a fourth operation of etching the other side of the light-emitting part so that the first passivation layer is exposed, a fifth operation of forming a mold part that surrounds the epitaxial die, a sixth operation of etching the mold part so that the second electrode pad is exposed, and etching the mold part and the first passivation layer so that the contact electrode is exposed, and a seventh operation of forming an extension electrode that electrically connects the second electrode pad and the exposed contact electrode.

According to the present invention, the above object is achieved by a method of manufacturing a semiconductor light-emitting device, including a first operation of preparing an epitaxial die that includes a light-emitting part having one side etched to a predetermined depth and configured to generate light, a first ohmic electrode formed on the light-emitting part and electrically connected to the light-emitting part, a second ohmic electrode formed on the etched portion on one side of the light-emitting part and electrically connected to the light-emitting part, a contact electrode formed on the first ohmic electrode and electrically connected to the first ohmic electrode, a temporary bonding layer formed to cover the contact electrode, a temporary substrate bonded to the temporary bonding layer, and a bonding pad layer formed to come into contact with a lower surface of the light-emitting part to be electrically connected to the second ohmic electrode and functioning as a vertical chip bonding pad, and preparing a substrate part on which a first electrode pad and a second electrode pad are each formed, a second operation of placing the epitaxial die on the first electrode pad, and bonding and electrically connecting the first electrode pad and the bonding pad layer through a bonding layer, a third operation of separating the temporary substrate and etching the temporary bonding layer to expose the contact electrode, a fourth operation of forming a mold part that surrounds the epitaxial die so that the contact electrode is exposed, a fifth operation of etching the mold part so that the second electrode pad is exposed, and a sixth operation of forming an extension electrode that electrically connects the second electrode pad and the exposed contact electrode.

According to the present invention, the above object is achieved by a method of manufacturing a semiconductor light-emitting device, including a first operation of preparing an epitaxial die that includes a light-emitting part configured to generate light, a first ohmic electrode formed on the light-emitting part and electrically connected to the light-emitting part, a passivation layer covering the first ohmic electrode and partially open to expose a portion of the first ohmic electrode, a contact electrode formed on the exposed first ohmic electrode and electrically connected to the first ohmic electrode, a temporary bonding layer formed on the passivation layer to cover the contact electrode, a temporary substrate bonded on the temporary bonding layer, and a bonding pad layer formed to come into contact with a lower surface of the light-emitting part to be electrically connected to the light-emitting part and functioning as a vertical chip bonding pad, and preparing a substrate part on which a first electrode pad and a second electrode pad are each formed, a second operation of placing the epitaxial die on the first electrode pad, and bonding and electrically connecting the first electrode pad and the bonding pad layer through a bonding layer, a third operation of separating the temporary substrate and etching the temporary bonding layer to expose the contact electrode, a fourth operation of forming a mold part that surrounds the epitaxial die so that the contact electrode is exposed, a fifth operation of etching the mold part so that the second electrode pad is exposed, and a sixth operation of forming an extension electrode that electrically connects the second electrode pad and the exposed contact electrode.

### Advantageous Effects

According to the present invention, it is possible to simultaneously satisfy both the advantage of a mini light-emitting diode (LED) manufacturing process, such as ease of defect classification, and low process and facility investment costs due to the use of existing general-purpose transfer equipment as is, and the advantage of a micro LED manufacturing process, such as a dramatic reduction in thickness and a reduction in chip die size by removing a sapphire final support substrate, thereby improving light output.

Further, according to the present invention, unlike conventional chip dies in which two electrodes, i.e., a positive electrode and a negative electrode, are exposed to the air, an epitaxial die of the present invention has a structure in which only one electrode is exposed to the air, and thus, although the epitaxial die is not electrically sorted, the epitaxial die can be optically sorted, allowing defects (NG) to be detected initially by a high-speed photoluminescence (PL) measurement method or the like using only optical characteristics (wavelength, full-width half maximum (FWHM), intensity, and the like).

Further, according to the present invention, an epitaxial die of the present invention has the advantage that a process of forming a p-ohmic contact electrode or an n-ohmic contact electrode, which requires a high-temperature heat treatment of 300° C. or higher, is completed at the operation of manufacturing the epitaxial die, so that the epitaxial die of the present invention does not require a high-temperature heat treatment process after transfer.

Further, according to the present invention, an epitaxial die of the present invention has the advantage of having a sapphire final support substrate attached, which can be removed after being transferred onto a targeted wafer, thereby enabling the die to be repositioned through conventional chip die transfer processes such as pick-and-place and replace.

Meanwhile, the effects of the present invention are not limited to the above-mentioned effects, and various effects may be included within the scope which is apparent to those skilled in the art from contents to be described below.

### DESCRIPTION OF DRAWINGS

FIG. 1 illustrates an overall view of an epitaxial die for a semiconductor light-emitting device according to a first embodiment of the present invention.

FIG. 2 illustrates an overall view of a semiconductor light-emitting device according to the first embodiment of the present invention.

FIG. 3 is a flowchart of a method of manufacturing the epitaxial die for a semiconductor light-emitting device according to the first embodiment of the present invention.

FIG. 4 illustrates a process of manufacturing the epitaxial die for a semiconductor light-emitting device according to the first embodiment of the present invention.

FIG. 5 is a flowchart of a method of manufacturing the semiconductor light-emitting device according to the first embodiment of the present invention.

FIG. 6 illustrates a process of manufacturing the semiconductor light-emitting device according to the first embodiment of the present invention.

FIG. 7 illustrates an overall view of an epitaxial die for a semiconductor light-emitting device according to a second embodiment of the present invention.

FIG. 8 illustrates an overall view of a semiconductor light-emitting device according to the second embodiment of the present invention.

FIG. 9 is a flowchart of a method of manufacturing the epitaxial die for a semiconductor light-emitting device according to the second embodiment of the present invention.

FIG. 10 illustrates a process of manufacturing the epitaxial die for a semiconductor light-emitting device according to the second embodiment of the present invention.

FIG. 11 is a flowchart of a method of manufacturing the semiconductor light-emitting device according to the second embodiment of the present invention.

FIG. 12 illustrates a process of manufacturing the semiconductor light-emitting device according to the second embodiment of the present invention.

FIG. 13 illustrates an overall view of an epitaxial die for a semiconductor light-emitting device according to a third embodiment of the present invention.

FIG. 14 illustrates an overall view of a semiconductor light-emitting device according to the third embodiment of the present invention.

FIG. 15 is a flowchart of a method of manufacturing the epitaxial die for a semiconductor light-emitting device according to the third embodiment of the present invention.

FIG. 16 illustrates a process of manufacturing the epitaxial die for a semiconductor light-emitting device according to the third embodiment of the present invention.

FIG. 17 is a flowchart of a method of manufacturing the semiconductor light-emitting device according to the third embodiment of the present invention.

FIG. 18 illustrates a process of manufacturing the semiconductor light-emitting device according to the third embodiment of the present invention.

FIG. 19 illustrates an overall view of an epitaxial die for a semiconductor light-emitting device according to a fourth embodiment of the present invention.

FIG. 20 illustrates an overall view of a semiconductor light-emitting device according to the fourth embodiment of the present invention.

FIG. 21 is a flowchart of a method of manufacturing the epitaxial die for a semiconductor light-emitting device according to the fourth embodiment of the present invention.

FIG. 22 illustrates a process of manufacturing the epitaxial die for a semiconductor light-emitting device according to the fourth embodiment of the present invention.

FIG. 23 is a flowchart of a method of manufacturing the semiconductor light-emitting device according to the fourth embodiment of the present invention.

FIG. 24 illustrates a process of manufacturing the semiconductor light-emitting device according to the fourth embodiment of the present invention.

FIG. 25 illustrates an overall view of an epitaxial die for a semiconductor light-emitting device according to a fifth embodiment of the present invention.

FIG. 26 illustrates an overall view of a semiconductor light-emitting device according to the fifth embodiment of the present invention.

FIG. 27 is a flowchart of a method of manufacturing the epitaxial die for a semiconductor light-emitting device according to the fifth embodiment of the present invention.

FIG. 28 illustrates a process of manufacturing the epitaxial die for a semiconductor light-emitting device according to the fifth embodiment of the present invention.

FIG. 29 is a flowchart of a method of manufacturing the semiconductor light-emitting device according to the fifth embodiment of the present invention.

FIG. 30 illustrates a process of manufacturing the semiconductor light-emitting device according to the fifth embodiment of the present invention.

### MODES OF THE INVENTION

Hereinafter, some embodiments of the present invention will be described in detail with reference to exemplary drawings. It should be noted that in adding reference numerals to the components of each drawing, the same components have the same number when possible, even though the same components are shown in different drawings

In addition, in describing the embodiments of the present invention, when detailed descriptions of related known structures or functions may obscure the gist of the present invention, the detailed description thereof will be omitted.

In addition, terms such as first, second, A, B, (a), (b), and the like may be used herein to describe components of the embodiments of the present invention. Each of these terms is not used to define an essence, order, or sequence of a corresponding component but used merely to distinguish the corresponding component from other component(s).

The present invention relates to an epitaxial die for a semiconductor light-emitting device that emits blue or green light, and a semiconductor light-emitting device including the same. In the present invention, a semi-finished light source die with a size less than or equal to that of a mini light-emitting diode (LED), which can be sorted and has the following characteristics, is defined as the epitaxial die of the present invention.

First, unlike conventional chip dies in which two electrodes, i.e., a positive electrode and a negative electrode, are both exposed to the outside, the epitaxial die of the present invention has a structure in which only one electrode is exposed to the outside. Accordingly, since the epitaxial die of the present invention has only one of the two electrodes (contact electrode) exposed to the air, although the epitaxial die is not electrically sorted by an electro luminescence (EL) measurement method, the epitaxial die can be optically sorted by a high-speed photo luminescence (PL) measurement method, allowing defects (NG) to be detected initially using only optical characteristics (wavelength, full-width half maximum (FWHM), intensity, and the like).

Second, in the epitaxial die of the present invention, a process of forming a p-ohmic contact electrode or an n-ohmic contact electrode, which requires a high-temperature heat treatment of 300° C. or higher, is completed at the operation of manufacturing the epitaxial die. Accordingly, the epitaxial die of the present invention has the advantage of not requiring a high-temperature heat treatment process after transfer.

Third, the epitaxial die of the present invention includes a sapphire final support substrate attached thereto, which is removed after transfer. Accordingly, the epitaxial die of the present invention has the advantage of being repositionable through conventional chip die transfer processes such as pick-and-place and replace.

That is, the epitaxial die of the present invention can simultaneously satisfy both the advantage of a mini light-emitting diode (LED) manufacturing process, such as ease of defect classification, and low process and facility investment costs due to the use of existing general-purpose transfer equipment as is, and the advantage of a micro LED manufacturing process, such as a dramatic reduction in thickness and a reduction in chip die size by removing a support substrate, which is the final substrate, thereby improving light output.

Hereinafter, with reference to the accompanying drawings, an epitaxial die 100 for a semiconductor light-emitting device according to a first embodiment of the present invention will be described in detail.

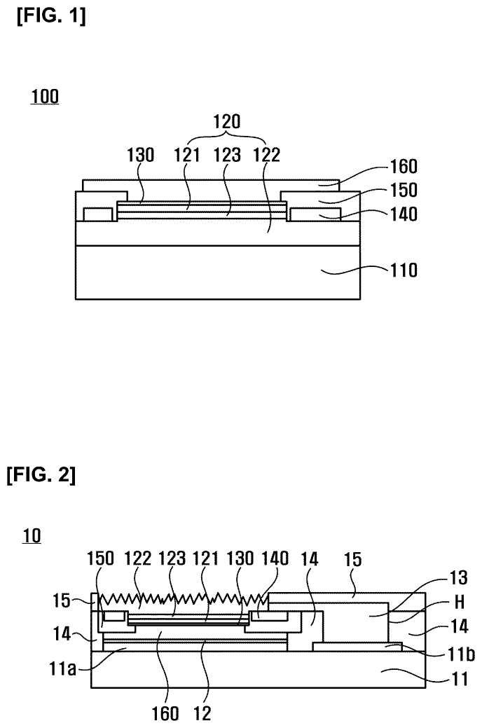

FIG. 1 illustrates an overall view of the epitaxial die for a semiconductor light-emitting device according to the first embodiment of the present invention.

As shown in FIG. 1, the epitaxial die 100 for a semiconductor light-emitting device according to the first embodiment of the present invention includes a growth substrate 110, a light-emitting part 120, a first ohmic electrode 130, a second ohmic electrode 140, a passivation layer 150, and a bonding pad layer 160.

The growth substrate 110 supports the light-emitting part 120, the first ohmic electrode 130, the second ohmic electrode 140, the passivation layer 150, and the bonding pad layer 160. A sapphire initial growth substrate 110 may be used, and the light-emitting part 120, which will be described below, can be epitaxially grown on the initial growth substrate 110.

Meanwhile, in the present invention, the initial growth substrate 110 on which the light-emitting part 120 is grown functions as a final support substrate that supports the light-emitting part 120, the first ohmic electrode 130, the second ohmic electrode 140, the passivation layer 150, and the bonding pad layer 160 after the epitaxial die 100 of the present invention is finally completed.

The light-emitting part 120 generates light, and in the present invention, in order to emit blue or green light, binary, ternary, and quaternary compounds such as indium nitride (InN), indium gallium nitride (InGaN), gallium nitride (GaN), aluminum gallium nitride (AlGaN), aluminum nitride (AlN), and aluminum gallium indium nitride (AlGaInN), which are Group III (Al, Ga, and In) nitride semiconductors, can be epitaxially grown on the growth substrate 110 by being placed in appropriate positions and sequences.

In particular, in order to emit blue or green light, high-quality indium gallium nitride (InGaN) with a high indium (In) composition, which is a Group III nitride semiconductor, should preferentially be formed on Group III nitride semiconductors composed of gallium nitride (GaN), aluminum gallium nitride (AlGaN), aluminum nitride (AlN), and aluminum gallium indium nitride (AlGaInN), but the present invention is not limited thereto.

More specifically, the light-emitting part 120 includes a first semiconductor region 121 (e.g., a p-type semiconductor region), an active region 123 (e.g., multi-quantum wells (MQWs)), and a second semiconductor region 122 (e.g., an n-type semiconductor region), and the light-emitting part 120 may have a structure in which the second semiconductor region 122, the active region 123, and the first semiconductor region 121 are epitaxially grown in this order on the growth substrate 110, and ultimately, may have an overall thickness typically ranging from about 5.0 to 8.0 μm, including multiple layers of group III nitrides, but the present invention is not limited thereto.

Each of the first semiconductor region 121, the active region 123, and the second semiconductor region 122 may be formed as either a single layer or multiple layers, and although not shown in the drawing, necessary layers, such as buffer regions, may be added before epitaxially growing the light-emitting part 120 on the sapphire initial growth substrate 110 to ensure the high quality of the epitaxially grown light-emitting part 120. For example, the buffer regions may include a nucleation layer and a compliant layer composed of an un-doped semiconductor region to relieve stress and improve thin-film quality and typically have a thickness of about 4.0 μm. In addition, when the growth substrate 110 is removed using a laser lift-off (LLO) technique, a sacrificial layer may be provided between the nucleation layer and the un-doped semiconductor region, and a seed layer may function as the sacrificial layer.

The second semiconductor region 122 has a second conductivity type (n-type), and is formed on the growth substrate 110. The second semiconductor region 122 may have a thickness of 2.0 to 3.5 μm.

The active region 123 generates light using the recombination of electrons and holes and is formed on the second semiconductor region 122. The active region 123 may have a multi-layer structure primarily composed of indium gallium nitride (InGaN) and gallium nitride (GaN) semiconductors, and may have a thickness of several tens of nanometers (nm).

The first semiconductor region 121 has a first conductivity type (p-type), and is formed on the active region 123. The first semiconductor region 121 may have a multi-layer structure primarily composed of aluminum gallium nitride (AlGaN) and gallium nitride (GaN) semiconductors, have a thickness ranging from several tens of nanometers (nm) to several micrometers (μm), and include a top surface having gallium (Ga) polarity.

That is, the active region 123 is interposed between the first semiconductor region 121 and the second semiconductor region 122, and light is generated when holes in the first semiconductor region 121, which is a p-type semiconductor region, and electrons in the second semiconductor region 122, which is an n-type semiconductor region, recombine in the active region 123.

At this time, a side portion of the light-emitting part 120 formed on the growth substrate 110, i.e., one side or both sides, may have a shape etched to a predetermined depth (i.e., both side surfaces of the light-emitting part 120 may each have a mesa-etched shape), and here, the predetermined depth may refer to up to the second semiconductor region 122, but the present invention is not limited thereto. Meanwhile, the surface of the etched portion of the second semiconductor region 122 of the light-emitting part 120 has gallium (Ga) polarity.

The first ohmic electrode 130 is electrically connected to the first semiconductor region 121 of the light-emitting part 120 and is formed on the first semiconductor region 121 so as to cover and come into surface contact with an upper surface of the first semiconductor region 121. At this time, the first semiconductor region 121 is electrically connected to the first ohmic electrode 130 through a p-ohmic contact.

The second ohmic electrode 140 is electrically connected to the second semiconductor region 122 of the light-emitting part 120 and is formed at an etched portion on a side portion, i.e., one side or both sides, of the second semiconductor region 122.

The first ohmic electrode 130 and the second ohmic electrode 140 may be basically formed of materials that have high transparency or reflectance and excellent electrical conductivity, but the present invention is not limited thereto. The materials of the first ohmic electrode 130 may include optically transparent materials such as indium tin oxide (ITO), ZnO, indium zinc oxide (IZO), indium gallium zinc oxide (IGZO), and titanium nitride (TiN), and optically reflective materials such as Ag, Al, Rh, Pt, Ni, Pd, Ru, Cu, and Au, and may be used alone or in combination.

Meanwhile, the materials of the second ohmic electrode 140 may include optically transparent materials such as indium tin oxide (ITO), ZnO, indium zinc oxide (IZO), indium gallium zinc oxide (IGZO), and titanium nitride (TiN), and metals such as Cr, Ti, Al, V, W, Re, and Au, and may be used alone or in combination.

At this time, as described above, the etched portion of the second semiconductor region 122 has a gallium (Ga) polarity surface, and the gallium (Ga) polarity surface is electrically connected to the second ohmic electrode 140 through an n-ohmic contact.

The passivation layer 150 covers a side portion of the first ohmic electrode 130 from the etched portion of the light-emitting part 120 via the second ohmic electrode 140, and when both sides of the light-emitting part 120 are each etched, the passivation layer may have a shape that covers one side of the first ohmic electrode 130 from the etched portion on one side of the light-emitting part 120 via the second ohmic electrode 140, and covers the other side of the first ohmic electrode 130 from the etched portion on the other side of the light-emitting part 120 via the second ohmic electrode 140. Due to the shape of the passivation layer 150, the second ohmic electrode 140 is interposed between the passivation layer 150 and the light-emitting part 120 and thus is not exposed.

The passivation layer 150 may be implemented with electrically insulating materials, and may include a single layer or multiple layers including at least one material from among silicon oxide, silicon nitride, metallic oxides including Al2O3, and organic insulators.

The bonding pad layer 160 functions as a vertical chip die bonding pad, and is formed on the first ohmic electrode 130 and the passivation layer 150 to be electrically connected to the first ohmic electrode 130. At this time, the bonding pad layer 160 is electrically connected to the first ohmic electrode 130, is exposed to the outside, and functions as a positive electrode.

The bonding pad layer 160 may basically include low melting point metals and noble metals such as gold (Au), silver (Ag), copper (Cu), and palladium (Pd), but the present invention is not limited thereto. In addition, the low melting point metals of the bonding pad layer 160 may be formed of metals such as In, Sn, Zn, and Pb alone or an alloy including these metals.

Accordingly, the epitaxial die 100 for a semiconductor light-emitting device according to the first embodiment of the present invention has a form in which the second ohmic electrode 140, which is a negative electrode, is interposed between the passivation layer 150 and the light-emitting part 120, and is not exposed, and only the bonding pad layer 160, which functions as a positive electrode, is exposed to the outside.

Hereinafter, with reference to the accompanying drawings, a semiconductor light-emitting device 10 according to the first embodiment of the present invention will be described in detail.

The semiconductor light-emitting device 10 of the present invention may be formed as a chip-on-board (COB) in which individual chips or epitaxial die units are directly transferred and connected to a substrate (such as a semiconductor wafer, a printed circuit board (PCB), or thin-film transistor (TFT) glass) on which circuit wiring and driving element regions are completed, a package-on-board (POB) in which package units (including 1, 2, 4, 9, 16, . . . , and n2 chips or epitaxial die units) manufactured using a fan-out package process known in conventional memory semiconductor technology are directly transferred and connected to a substrate on which circuit wiring and driving element regions (such as a semiconductor wafer, a PCB, or TFT glass) are completed, or an interposer using a temporary substrate on which circuit wiring and driving element regions are not completed, but is not limited thereto, and will be described herein as being formed as the COB type for convenience of description.

FIG. 2 illustrates an overall view of the semiconductor light-emitting device according to the first embodiment of the present invention.

As shown in FIG. 2, the semiconductor light-emitting device 10 according to the first embodiment of the present invention includes a substrate part 11, the epitaxial die 100, a bonding layer 12, an extension electrode 13, a mold part 14, and a black matrix 15.

The substrate part 11 supports the epitaxial die 100 that is bonded thereto, and a first electrode pad 11a and a second electrode pad 11b are each formed on an upper surface of the substrate part 11. The substrate part 11 may refer to a semiconductor wafer, a PCB, TFT glass, an interposer, or the like, but the present invention is not limited thereto.

Further, the first electrode pad 11a may refer to an individual positive electrode, and the second electrode pad 11b may refer to a common negative electrode. For example, after three epitaxial dies 100 emitting blue, green, and red light are respectively placed on three individual positive electrodes and bonded to form a single pixel, each of the epitaxial dies 100 may be electrically connected to the common negative electrode.

The epitaxial die 100 is placed upside down on the first electrode pad 11a of the substrate part 11 and includes a light-emitting part 120, a first ohmic electrode 130, a second ohmic electrode 140, a passivation layer 150, and a bonding pad layer 160.

Here, the light-emitting part 120, the first ohmic electrode 130, the second ohmic electrode 140, the passivation layer 150, and the bonding pad layer 160 are the same as those of the epitaxial die 100 for the semiconductor light-emitting device 10 according to the first embodiment of the present invention described above, and thus redundant descriptions will be omitted.

Meanwhile, in the upside-down epitaxial die 100, a surface texture pattern of a predetermined shape or an irregular shape may be formed on an upper surface of the light-emitting part 120, i.e., an upper surface of the second semiconductor region 122, in order to extract as much light generated in the active region into the air as possible.

The bonding layer 12 electrically connects the first electrode pad 11a of the substrate part 11 and the bonding pad layer 160 of the epitaxial die 100 by bonding them together, and may include low melting point metals and noble metals such as gold (Au), silver (Ag), copper (Cu), and palladium (Pd) similar to or the same as the bonding pad layer 160 of the epitaxial die 100, but the present invention is not limited thereto.

The extension electrode 13 electrically connects the second electrode pad 11b of the substrate part 11 and the second ohmic electrode 140 of the epitaxial die 100, and the extension electrode 13 is formed to extend vertically from an upper portion of the second electrode pad 11b to above the mold part 14 through a through hole H of the mold part 14, which will be described below, and then be bent toward the second ohmic electrode 140 to come into contact with and be electrically connected to the second ohmic electrode 140.

The extension electrode 13 may include optically transparent and electrically conductive ceramics, such as ITO and TiN, or low melting point metals and noble metals such as gold (Au), silver (Ag), copper (Cu), and palladium (Pd) similar to or the same as the above-described materials of the bonding layer 12, but the present invention is not limited thereto.

At this time, the light-emitting part 120 has a shape in which one side is etched to partially or entirely expose the second ohmic electrode 140, and the extension electrode 13 electrically connects the exposed second ohmic electrode 140 to the second electrode pad 11b.

The mold part 14 surrounds and supports the epitaxial die 100 and the extension electrode 13, which are disposed to form a vertical structure, and is formed so that the upper surface of the light-emitting part 120 of the epitaxial die 100 and an upper surface of the extension electrode 13 are exposed. In the mold part 14, the through hole H is formed above the second electrode pad 11b, and the extension electrode 13 is electrically connected to the second ohmic electrode 140 through the through hole H.

Meanwhile, laser drilling may be used to form the through hole H, and in this case, the mold part 14 may be made of materials that enable laser direct structuring (LDS) or laser direct imaging (LDI).

The black matrix (BM) 15 covers the exposed upper surfaces of the extension electrode 13 and the mold part 14, and may be formed using photolithography and spin coating processes, but the present invention is not limited thereto.

In addition, the black matrix 15 may be formed of a metal thin film or a carbon-based organic material with an optical density of 3.5 or higher, but the present invention is not limited thereto. More specifically, representative examples thereof include a chromium (Cr) monolayer film, a chromium (Cr)/chromium oxide (CrOx) bilayer film, manganese dioxide (MnO2), an organic black matrix, graphite, and a pigment dispersion composition (prepared by blending a block copolymer resin with pigment-affinity groups such as amino, hydroxyl, and carboxyl groups, with carbon black as a medium, and mixing the blend with a solvent and a dispersing agent).

Hereinafter, with reference to the accompanying drawings, a method (S100) of manufacturing the epitaxial die for a semiconductor light-emitting device according to the first embodiment of the present invention will be described in detail.

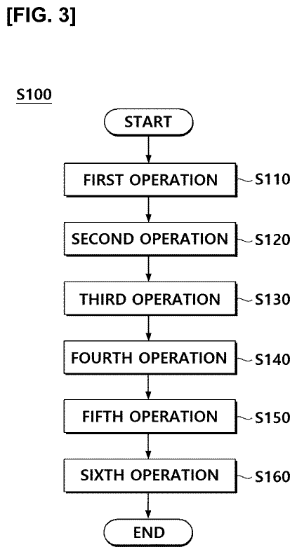

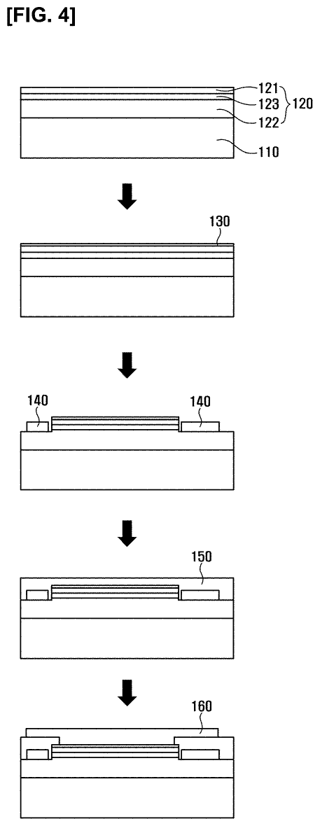

FIG. 3 is a flowchart of the method of manufacturing the epitaxial die for a semiconductor light-emitting device according to the first embodiment of the present invention, and FIG. 4 illustrates a process of manufacturing the epitaxial die for a semiconductor light-emitting device according to the first embodiment of the present invention.

As shown in FIGS. 3 and 4, the method (S100) of manufacturing the epitaxial die for a semiconductor light-emitting device according to the first embodiment of the present invention includes a first operation S110, a second operation S120, a third operation S130, a fourth operation S140, a fifth operation S150, and a sixth operation S160. However, it is of course possible that the order of the processes shown in FIGS. 3 and 4 can be changed.

The first operation S110 is an operation of preparing a growth substrate 110. The growth substrate 110 is where a light-emitting part 120, which will be described below, is epitaxially grown, and supports the light-emitting part 120, a first ohmic electrode 130, a second ohmic electrode 140, a passivation layer 150, and a bonding pad layer 160. A sapphire initial growth substrate 110 may be used.

That is, in the present invention, the initial growth substrate 110 on which the light-emitting part 120 is grown functions as a final support substrate that supports the light-emitting part 120, the first ohmic electrode 130, the second ohmic electrode 140, the passivation layer 150, and the bonding pad layer 160 after the epitaxial die 100 of the present invention is finally completed.

The second operation S120 is an operation of forming the light-emitting part 120 on the growth substrate 110. That is, more specifically, the light-emitting part 120 includes a first semiconductor region 121 (e.g., a p-type semiconductor region), an active region 123 (e.g., MQWs), and a second semiconductor region 122 (e.g., an n-type semiconductor region), and in the second operation S120, the second semiconductor region 122, the active region 123, and the first semiconductor region 121 are epitaxially grown in this order on the growth substrate 110.

The third operation S130 is an operation of forming the first ohmic electrode 130 that is electrically connected to the first semiconductor region 121 by covering so as to come into surface contact with an upper surface of the first semiconductor region 121 of the light-emitting part 120. At this time, heat treatment is selectively performed at a high temperature of 300° C. or higher so that the first semiconductor region 121 forms a p-ohmic contact with the first ohmic electrode 130.

The fourth operation S140 is an operation of etching a side portion of each of the light-emitting part 120 and the first ohmic electrode 130 to a predetermined depth, and forming the second ohmic electrode 140 in the etched portion.

That is, after etching one side or both sides of the light-emitting part 120 to a predetermined depth (both side surfaces of the light-emitting part 120 may each have a mesa-etched shape), the second ohmic electrode 140 is formed on each etched portion on one side or both sides of the second semiconductor region 122 of the light-emitting part 120. At this time, the surface of the etched portion of the second semiconductor region 122 has gallium (Ga) polarity, and the gallium (Ga) polarity surface needs to be heat treated at a high temperature of 300° C. or higher to form an n-ohmic contact with the second ohmic electrode 140.

The fifth operation S150 is an operation of forming the passivation layer 150 that covers the first ohmic electrode 130 from the etched portion of the light-emitting part 120 via the second ohmic electrode 140. That is, when both sides of the light-emitting part 120 are each etched, the passivation layer 150 is formed to cover one side of the first ohmic electrode 130 via the second ohmic electrode 140 from the etched portion on one side of the light-emitting part 120 and to cover the other side of the first ohmic electrode 130 via the second ohmic electrode 140 from the etched portion on the other side of the light-emitting part 120. Due to the shape of the passivation layer 150, the second ohmic electrode 140 is interposed between the passivation layer 150 and the light-emitting part 120 and thus is not exposed.

The sixth operation S160 is an operation of etching a portion of the passivation layer 150 to expose the first ohmic electrode 130 and forming the bonding pad layer 160, which functions as a vertical chip bonding pad, to come into contact with the exposed first ohmic electrode 130. The bonding pad layer 160 functions as a vertical chip bonding pad, is electrically connected to the first ohmic electrode 130, and functions as a positive electrode.

After the basic structure of the epitaxial die 100 is formed through the above-described first operation S110 to sixth operation S160, processes such as grinding, dicing, probing, and sorting are performed.

Hereinafter, with reference to the accompanying drawings, a method (S10) of manufacturing the semiconductor light-emitting device according to the first embodiment of the present invention will be described in detail.

The semiconductor light-emitting device 10 of the present invention may be formed as a COB in which individual chips or epitaxial die units are directly transferred and connected to a substrate (such as a semiconductor wafer, a PCB, or TFT glass) on which circuit wiring and driving element regions are completed, a POB in which package units (including 1, 2, 4, 9, 16, . . . , and n2 chips or epitaxial die units) manufactured using a fan-out package process known in conventional memory semiconductor technology are directly transferred and connected to a substrate on which circuit wiring and driving element regions (such as a semiconductor wafer, a PCB, or TFT glass) are completed, or an interposer using a temporary substrate on which circuit wiring and driving element regions are not completed, but is not limited thereto, and will be described herein as being formed as the COB type for convenience of description.

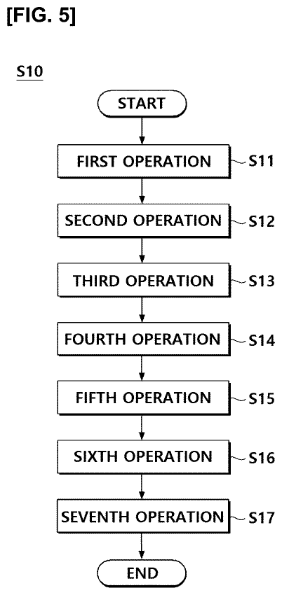

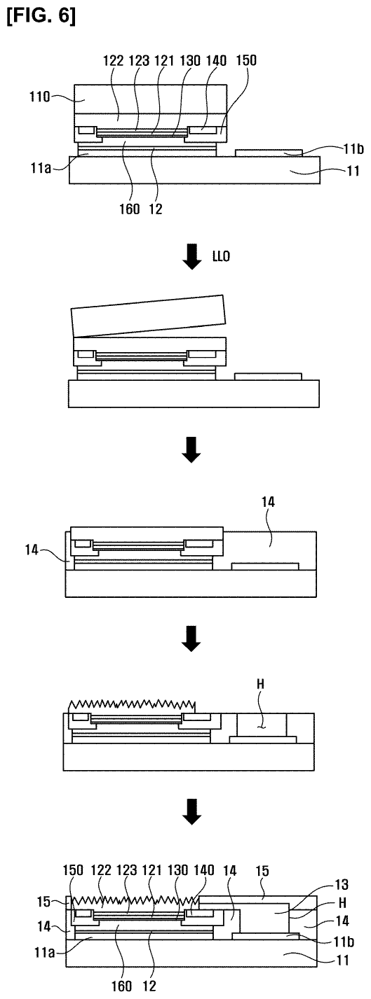

FIG. 5 is a flowchart of the method of manufacturing the semiconductor light-emitting device according to the first embodiment of the present invention, and FIG. 6 illustrates a process of manufacturing the semiconductor light-emitting device according to the first embodiment of the present invention.

As shown in FIGS. 5 and 6, the method (S10) of manufacturing the semiconductor light-emitting device according to the first embodiment of the present invention includes a first operation S11, a second operation S12, a third operation S13, a fourth operation S14, a fifth operation S15, a sixth operation S16, and a seventh operation S17. However, it is of course possible that the order of the processes shown in FIGS. 5 and 6 can be changed.

The first operation S11 is an operation of preparing the epitaxial die 100 for a semiconductor light-emitting device according to the first embodiment of the present invention and a substrate part 11 on which a first electrode pad 11a and a second electrode pad 11b are each formed. The substrate part 11 may refer to a semiconductor wafer, a PCB, TFT glass, an interposer, or the like, but the present invention is not limited thereto.

The second operation S12 is an operation of placing the epitaxial die 100 upside down on the first electrode pad 11a, which is an individual positive electrode, and electrically connecting the first electrode pad 11a and the bonding pad layer 160 by bonding them through a bonding layer 12. At this time, the placement and bonding of the epitaxial die 100 can be accomplished through typical chip die transfer processes such as pick-and-place, roll-to-roll (R2R), and stamps (made from materials such as polydimethylsiloxane (PDMS), silicon (Si), quartz, and glass), which are commonly known tools used in representative processes of massive transfer.

Meanwhile, when it is necessary to achieve objectives such as (1) high precision placement of an epitaxial die 100, (2) an epitaxial die 100 with a ultra-small size of less than 50 μm×50 μm, and (3) an epitaxial die 100 having a self-assembly structure, additional masking media (such as a photoresist, ceramics (like glass, quartz, and alumina), or an invar fine metal mask (FMM)) or processes may be employed before the placement and bonding of the epitaxial die 100.

The third operation S13 is an operation of separating the growth substrate 110 of the epitaxial die 100. At this time, in the third operation S13, the growth substrate 110 may be separated from the light-emitting part 120, i.e., the second semiconductor region 122, using an LLO technique to expose an upper surface of the second semiconductor region 122. Here, the LLO technique refers to a technique of separating the growth substrate 110 from the epitaxially grown layers by irradiating a rear surface of the transparent growth substrate 110 with an ultraviolet (UV) laser beam having a uniform light output and beam profile, and a single wavelength.

The fourth operation S14 is an operation of forming a mold part 14 surrounding the epitaxial die 100 so that an upper surface of the light-emitting part 120, that is, the upper surface of the second semiconductor region 122, is exposed. At this time, the mold part 14 may be made of materials that enable LDS or LDI to allow laser drilling in the sixth operation S16 to be described below.

The fifth operation S15 is an operation of etching one side of the light-emitting part 120 so that the second ohmic electrode 140 is exposed. That is, the fifth operation S15 is an operation of etching one side of the second semiconductor region 122 through dry etching or wet etching to expose the second ohmic electrode 140, which was interposed between the second semiconductor region 122 and the passivation layer 150 and was not exposed.

Meanwhile, in the fifth operation S15, a surface texture pattern of a predetermined shape or an irregular shape may be formed on the upper surface of the light-emitting part 120, i.e., the upper surface of the second semiconductor region 122, of the upside-down epitaxial die 100 to extract as much light generated in the active region 123 into the air as possible.

The sixth operation S16 is an operation of etching the mold part 14 to expose the second electrode pad 11b and forming an extension electrode 13 that electrically connects the second electrode pad 11b to the second ohmic electrode 140. That is, in the sixth operation S16, a through hole H is formed above the second electrode pad 11b using laser drilling, and the extension electrode 13 is formed to extend vertically from an upper portion of the second electrode pad 11b to above the mold part 14 through the through hole H and then be bent toward the second ohmic electrode 140, thereby electrically connecting the second ohmic electrode 140 and the second electrode pad 11b, which is a common negative electrode.

The seventh operation S17 is an operation of forming a black matrix 15 that covers the extension electrode 13 and the mold part 14. The black matrix 15 may be formed using photolithography and spin coating processes, but the present invention is not limited thereto.

Hereinafter, with reference to the accompanying drawings, an epitaxial die 200 for a semiconductor light-emitting device according to a second embodiment of the present invention will be described in detail.

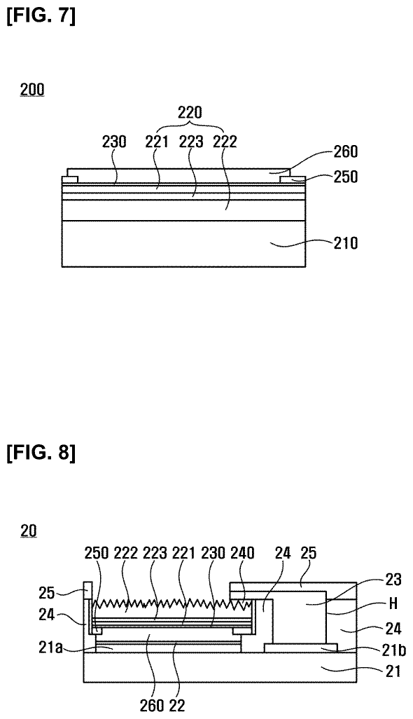

FIG. 7 illustrates an overall view of the epitaxial die for a semiconductor light-emitting device according to the second embodiment of the present invention.

As shown in FIG. 7, the epitaxial die 200 for a semiconductor light-emitting device according to the second embodiment of the present invention includes a growth substrate 210, a light-emitting part 220, a first ohmic electrode 230, a passivation layer 250, and a bonding pad layer 260.

The growth substrate 210 supports the light-emitting part 220, the first ohmic electrode 230, the passivation layer 250, and the bonding pad layer 260, a sapphire initial growth substrate 210 may be used, and the light-emitting part 220 to be described below may be epitaxially grown on the growth substrate 210.

Meanwhile, in the present invention, the initial growth substrate 210 on which the light-emitting part 220 is grown functions as a final support substrate that supports the light-emitting part 220, the first ohmic electrode 230, the passivation layer 250, and the bonding pad layer 260 after the epitaxial die 200 of the present invention is finally completed.

The light-emitting part 220 generates light, and in the present invention, in order to emit blue or green light, binary, ternary, and quaternary compounds such as indium nitride (InN), indium gallium nitride (InGaN), gallium nitride (GaN), aluminum gallium nitride (AlGaN), aluminum nitride (AlN), and aluminum gallium indium nitride (AlGaInN), which are Group III (Al, Ga, and In) nitride semiconductors, can be epitaxially grown on the growth substrate 210 by being placed in appropriate positions and sequences.

In particular, in order to emit blue or green light, high-quality indium gallium nitride (InGaN) with a high indium (In) composition, which is a Group III nitride semiconductor, should preferentially be formed on Group III nitride semiconductors composed of gallium nitride (GaN), aluminum gallium nitride (AlGaN), aluminum nitride (AlN), and aluminum gallium indium nitride (AlGaInN), but the present invention is not limited thereto.

More specifically, the light-emitting part 220 includes a first semiconductor region 221 (e.g., a p-type semiconductor region), an active region 223 (e.g., MQWs), and a second semiconductor region 222 (e.g., an n-type semiconductor region), and the light-emitting part 220 may have a structure in which the second semiconductor region 222, the active region 223, and the first semiconductor region 221 are epitaxially grown in this order on the growth substrate 210, and ultimately, may have an overall thickness typically ranging from about 5.0 to 8.0 μm, including multiple layers of group III nitrides, but the present invention is not limited thereto.

Each of the first semiconductor region 221, the active region 223, and the second semiconductor region 222 may be formed as either a single layer or multiple layers, and although not shown in the drawing, necessary layers, such as buffer regions, may be added before epitaxially growing the light-emitting part 220 on the sapphire initial growth substrate 210 to ensure the high quality of the epitaxially grown light-emitting part 220. For example, the buffer regions may include a nucleation layer and a compliant layer composed of an un-doped semiconductor region to relieve stress and improve thin-film quality and typically have a thickness of about 4.0 μm. In addition, when the growth substrate 210 is removed using an LLO technique, a sacrificial layer may be provided between the nucleation layer and the un-doped semiconductor region, and a seed layer may function as the sacrificial layer.

The second semiconductor region 222 has a second conductivity type (n-type), and is formed on the growth substrate 210. The second semiconductor region 222 may have a thickness of 2.0 to 3.5 μm.

The active region 223 generates light using the recombination of electrons and holes and is formed on the second semiconductor region 222. The active region 223 may have a multi-layer structure primarily composed of indium gallium nitride (InGaN) and gallium nitride (GaN) semiconductors, and may have a thickness of several tens of nanometers (nm).

The first semiconductor region 221 has a first conductivity type (p-type), and is formed on the active region 223. The first semiconductor region 221 may have a multi-layer structure primarily composed of aluminum gallium nitride (AlGaN) and gallium nitride (GaN) semiconductors, have a thickness ranging from several tens of nanometers (nm) to several micrometers (μm), and include a top surface having gallium (Ga) polarity.

That is, the active region 223 is interposed between the first semiconductor region 221 and the second semiconductor region 222, and light is generated when holes in the first semiconductor region 221, which is a p-type semiconductor region, and electrons in the second semiconductor region 222, which is an n-type semiconductor region, recombine in the active region 223.

The first ohmic electrode 230 is electrically connected to the first semiconductor region 221 of the light-emitting part 220 and is formed on the first semiconductor region 221 so as to cover and come into surface contact with an upper surface of the first semiconductor region 221. At this time, the first semiconductor region 221 is electrically connected to the first ohmic electrode 230 through a p-ohmic contact.

The first ohmic electrode 230 may be basically formed of materials that have high transparency or reflectance and excellent electrical conductivity, but the present invention is not limited thereto. The materials of the first ohmic electrode 230 may include optically transparent materials such as indium tin oxide (ITO), ZnO, indium zinc oxide (IZO), indium gallium zinc oxide (IGZO), and titanium nitride (TiN), and optically reflective materials such as Ag, Al, Rh, Pt, Ni, Pd, Ru, Cu, and Au, and may be used alone or in combination.

The passivation layer 250 covers a side portion of the first ohmic electrode 230, and may have a shape that covers each of one side and the other side of the first ohmic electrode 230.

The passivation layer 250 may be implemented with electrically insulating materials, and may include a single layer or multiple layers including at least one material from among silicon oxide, silicon nitride, metallic oxides including Al2O3, and organic insulators.

The bonding pad layer 260 functions as a vertical chip die bonding pad, and is formed on the first ohmic electrode 230 and the passivation layer 250 to be electrically connected to the first ohmic electrode 230. At this time, the bonding pad layer 260 is electrically connected to the first ohmic electrode 230, is exposed to the outside, and functions as a positive electrode.

The bonding pad layer 260 may basically include low melting point metals and noble metals such as gold (Au), silver (Ag), copper (Cu), and palladium (Pd), but the present invention is not limited thereto. In addition, the low melting point metals of the bonding pad layer 260 may be formed of metals such as In, Sn, Zn, and Pb alone or an alloy including these metals.

Meanwhile, in the epitaxial die 200 for a semiconductor light-emitting device according to the second embodiment of the present invention, a second ohmic electrode is not formed because the second ohmic electrode is formed during the manufacturing process of the semiconductor light-emitting device. As a result, only the bonding pad layer 260, which functions as a positive electrode, is exposed to the outside.

Hereinafter, with reference to the accompanying drawings, a semiconductor light-emitting device 20 according to the second embodiment of the present invention will be described in detail.

The semiconductor light-emitting device 20 of the present invention may be formed as a COB in which individual chips or epitaxial die units are directly transferred and connected to a substrate (such as a semiconductor wafer, a PCB, or TFT glass) on which circuit wiring and driving element regions are completed, a POB in which package units (including 1, 2, 4, 9, 16, . . . , and n2 chips or epitaxial die units) manufactured using a fan-out package process known in conventional memory semiconductor technology are directly transferred and connected to a substrate on which circuit wiring and driving element regions (such as a semiconductor wafer, a PCB, or TFT glass) are completed, or an interposer using a temporary substrate on which circuit wiring and driving element regions are not completed, but is not limited thereto, and will be described herein as being formed as the COB type for convenience of description.

FIG. 8 illustrates an overall view of the semiconductor light-emitting device according to the second embodiment of the present invention.

As shown in FIG. 8, the semiconductor light-emitting device 20 according to the second embodiment of the present invention includes a substrate part 21, the epitaxial die 200, a bonding layer 22, a second ohmic electrode 240, an extension electrode 23, a mold part 24, and a black matrix 25.

The substrate part 21 supports the epitaxial die 200 that is bonded thereto, and a first electrode pad 21a and a second electrode pad 21b are each formed on an upper surface of the substrate part 21. The substrate part 21 may refer to a semiconductor wafer, a PCB, TFT glass, an interposer, or the like, but the present invention is not limited thereto.

Further, the first electrode pad 21a may refer to an individual positive electrode, and the second electrode pad 21b may refer to a common negative electrode. For example, after three epitaxial dies 200 emitting blue, green, and red light are respectively placed on three individual positive electrodes and bonded to form a single pixel, each of the epitaxial dies 200 may be electrically connected to the common negative electrode.

The epitaxial die 200 is placed upside down on the first electrode pad 21a of the substrate part 21 and includes a light-emitting part 220, a first ohmic electrode 230, a passivation layer 250, and a bonding pad layer 260.

Here, the light-emitting part 220, the first ohmic electrode 230, the passivation layer 250, and the bonding pad layer 260 are the same as those of the epitaxial die 200 for the semiconductor light-emitting device 20 according to the second embodiment of the present invention as described above, and thus redundant descriptions will be omitted.

Meanwhile, in the upside-down epitaxial die 200, a surface texture pattern of a predetermined shape or an irregular shape may be formed on an upper surface of the light-emitting part 220, i.e., an upper surface of the second semiconductor region 222, in order to extract as much light generated in the active region into the air as possible.

The bonding layer 22 electrically connects the first electrode pad 21a of the substrate part 21 and the bonding pad layer 260 of the epitaxial die 200 by bonding them together, and may include low melting point metals and noble metals such as gold (Au), silver (Ag), copper (Cu), and palladium (Pd) similar to or the same as the bonding pad layer 260 of the epitaxial die 200, but the present invention is not limited thereto.

The second ohmic electrode 240 is electrically connected to the light-emitting part 220, i.e., the second semiconductor region 222, and is formed to be exposed on an upper surface of the second semiconductor region 222. The second ohmic electrode 240 may be basically formed of materials that have high transparency or reflectance and excellent electrical conductivity, but the present invention is not limited thereto. The materials of the second ohmic electrode 240 may include optically transparent materials such as indium tin oxide (ITO), ZnO, indium zinc oxide (IZO), indium gallium zinc oxide (IGZO), and titanium nitride (TiN), and metals such as Cr, Ti, Al, V, W, Re, and Au, and may be used alone or in combination.

At this time, the upper surface of the second semiconductor region 222 has a nitrogen (N) polar surface, which forms an n-ohmic contact and is electrically connected to the second ohmic electrode 240.

The extension electrode 23 electrically connects the second electrode pad 21b of the substrate part 21 and the second ohmic electrode 240 formed on the epitaxial die 200, and the extension electrode 23 is formed to extend vertically from an upper portion of the second electrode pad 21b to above the mold part 24 through a through hole H of the mold part 24, which will be described below, and then be bent toward the second ohmic electrode 240 to come into contact with and be electrically connected to the second ohmic electrode 240.

The extension electrode 23 may include optically transparent and electrically conductive ceramics, such as ITO and TiN, or low melting point metals and noble metals such as gold (Au), silver (Ag), copper (Cu), and palladium (Pd) similar to or the same as the above-described materials of the bonding layer 22, but the present invention is not limited thereto.

The mold part 24 surrounds and supports the epitaxial die 200 and the extension electrode 23, which are disposed to form a vertical structure, and is formed so that the upper surface of the light-emitting part 220 of the epitaxial die 200 and an upper surface of the extension electrode 23 are exposed. In the mold part 24, the through hole H is formed above the second electrode pad 21b, and the extension electrode 23 is electrically connected to the second ohmic electrode 240 through the through hole H.

Meanwhile, laser drilling may be used to form the through hole H, and in this case, the mold part 24 may be made of materials that enable LDS or LDI.

The black matrix (BM) 25 covers the exposed upper surfaces of the extension electrode 23 and the mold part 24, and may be formed using photolithography and spin coating processes, but the present invention is not limited thereto.

The black matrix 25 may be formed of a metal thin film or a carbon-based organic material with an optical density of 3.5 or higher, but the present invention is not limited thereto. More specifically, representative examples thereof include a chromium (Cr) monolayer film, a chromium (Cr)/chromium oxide (CrOx) bilayer film, manganese dioxide (MnO2), an organic black matrix, graphite, and a pigment dispersion composition (prepared by blending a block copolymer resin with pigment-affinity groups such as amino, hydroxyl, and carboxyl groups, with carbon black as a medium, and mixing the blend with a solvent and a dispersing agent).

Hereinafter, with reference to the accompanying drawings, a method (S200) of manufacturing the epitaxial die for a semiconductor light-emitting device according to the second embodiment of the present invention will be described in detail.

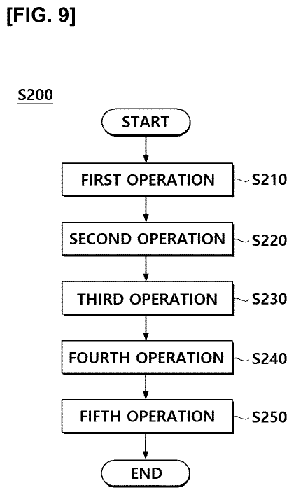

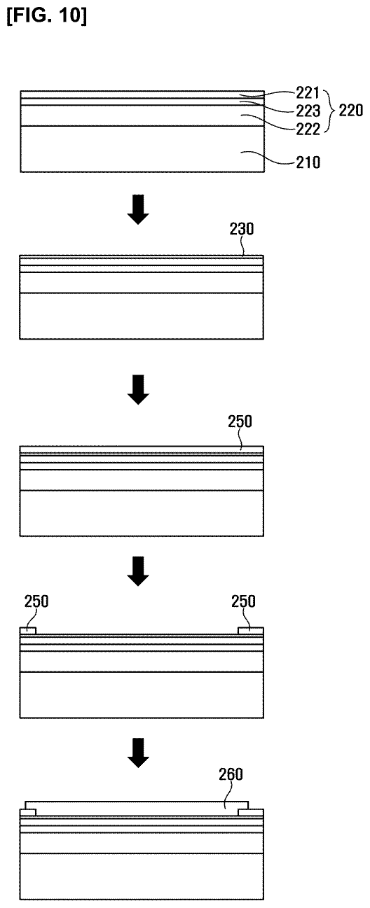

FIG. 9 is a flowchart of the method of manufacturing the epitaxial die for a semiconductor light-emitting device according to the second embodiment of the present invention, and FIG. 10 illustrates a process of manufacturing the epitaxial die for a semiconductor light-emitting device according to the second embodiment of the present invention.

As shown in FIGS. 9 and 10, the method (S200) of manufacturing the epitaxial die for a semiconductor light-emitting device according to the second embodiment of the present invention includes a first operation S210, a second operation S220, a third operation S230, a fourth operation S240, and a fifth operation S250. However, it is of course possible that the order of the processes shown in FIGS. 9 and 10 can be changed.

The first operation S210 is an operation of preparing a growth substrate 210. The growth substrate 210 is where a light-emitting part 220, which will be described below, is epitaxially grown, and supports the light-emitting part 220, a first ohmic electrode 230, a passivation layer 250, and a bonding pad layer 260. A sapphire initial growth substrate 210 may be used.

That is, in the present invention, the initial growth substrate 210 on which the light-emitting part 220 is grown functions as a final support substrate that supports the light-emitting part 220, the first ohmic electrode 230, the passivation layer 250, and the bonding pad layer 260 after the epitaxial die 200 of the present invention is finally completed.

The second operation S220 is an operation of forming the light-emitting part 220 on the growth substrate 210. That is, more specifically, the light-emitting part 220 includes a first semiconductor region 221 (e.g., a p-type semiconductor region), an active region 223 (e.g., MQWs), and a second semiconductor region 222 (e.g., an n-type semiconductor region), and in the second operation S220, the second semiconductor region 222, the active region 223, and the first semiconductor region 221 are epitaxially grown in this order on the growth substrate 210.

The third operation S230 is an operation of forming the first ohmic electrode 230 that is electrically connected to the first semiconductor region 221 by covering so as to come into surface contact with an upper surface of the first semiconductor region 221 of the light-emitting part 220. At this time, heat treatment is selectively performed at a high temperature of 300° C. or higher so that the first semiconductor region 221 forms a p-ohmic contact with the first ohmic electrode 230.

The fourth operation S240 is an operation of forming the passivation layer 250 that covers the first ohmic electrode 230.

The fifth operation S250 is an operation of etching a portion of the passivation layer 250 to expose the first ohmic electrode 230 and forming the bonding pad layer 260, which functions as a vertical chip bonding pad, to come into contact with the exposed first ohmic electrode 230. The bonding pad layer 260 functions as a vertical chip bonding pad, is electrically connected to the first ohmic electrode 230, and functions as a positive electrode.

After the basic structure of the epitaxial die is formed through the above-described first operation S210 to fifth operation S250, processes such as grinding, dicing, probing, and sorting are performed.

Hereinafter, with reference to the accompanying drawings, a method (S20) of manufacturing the semiconductor light-emitting device according to the second embodiment of the present invention will be described in detail.

The semiconductor light-emitting device of the present invention may be formed as a COB in which individual chips or epitaxial die units are directly transferred and connected to a substrate (such as a semiconductor wafer, a PCB, or TFT glass) on which circuit wiring and driving element regions are completed, a POB in which package units (including 1, 2, 4, 9, 16, . . . , and n2 chips or epitaxial die units) manufactured using a fan-out package process known in conventional memory semiconductor technology are directly transferred and connected to a substrate on which circuit wiring and driving element regions (such as a semiconductor wafer, a PCB, or TFT glass) are completed, or an interposer using a temporary substrate on which circuit wiring and driving element regions are not completed, but is not limited thereto, and will be described herein as being formed as the COB type for convenience of description.

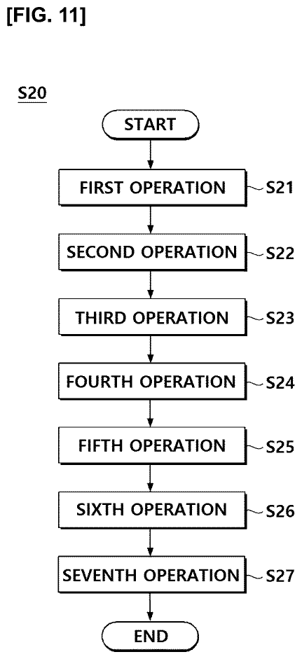

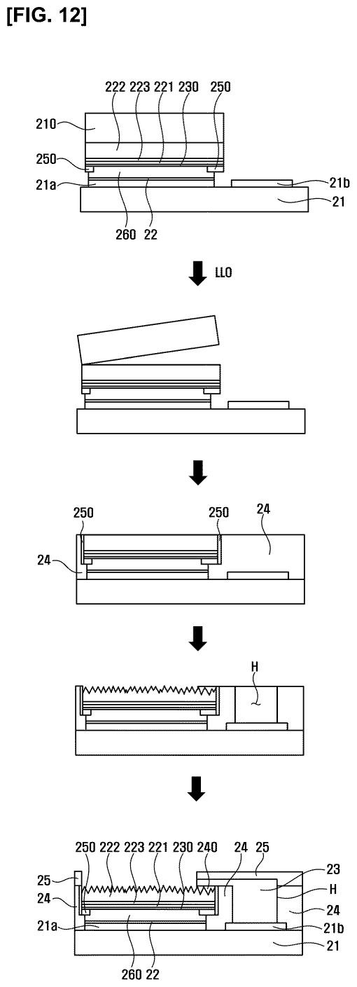

FIG. 11 is a flowchart of the method of manufacturing the semiconductor light-emitting device according to the second embodiment of the present invention, and FIG. 12 illustrates a process of manufacturing the semiconductor light-emitting device according to the second embodiment of the present invention.

As shown in FIGS. 11 and 12, the method (S20) of manufacturing the semiconductor light-emitting device according to the second embodiment of the present invention includes a first operation S21, a second operation S22, a third operation S23, a fourth operation S24, a fifth operation S25, a sixth operation S26, and a seventh operation S27. However, it is of course possible that the order of the processes shown in FIGS. 11 and 12 can be changed.

The first operation S21 is an operation of preparing the epitaxial die 200 for a semiconductor light-emitting device according to the second embodiment of the present invention and a substrate part 21 on which a first electrode pad 21a and a second electrode pad 21b are each formed. The substrate part 21 may refer to a semiconductor wafer, a PCB, TFT glass, an interposer, or the like, but the present invention is not limited thereto.

The second operation S22 is an operation of placing the epitaxial die 200 upside down on the first electrode pad 21a, which is an individual positive electrode, and electrically connecting the first electrode pad 21a and the bonding pad layer 260 by bonding them through a bonding layer 22. At this time, the placement and bonding of the epitaxial die 200 can be accomplished through typical chip die transfer processes such as pick-and-place, roll-to-roll (R2R), and stamps (made from materials such as polydimethylsiloxane (PDMS), silicon (Si), quartz, and glass), which are commonly known tools used in representative processes of massive transfer.

Meanwhile, when it is necessary to achieve objectives such as (1) high precision placement of an epitaxial die 200, (2) an epitaxial die 200 with a ultra-small size of less than 50 μm×50 μm, and (3) an epitaxial die 200 having a self-assembly structure, additional masking media (such as a photoresist, ceramics (like glass, quartz, and alumina), or an invar FMM) or processes may be employed before the placement and bonding of the epitaxial die 200.

The third operation S23 is an operation of separating the growth substrate 210 of the epitaxial die 200. At this time, in the third operation S23, the growth substrate 210 may be separated from the light-emitting part 220, i.e., the second semiconductor region 222, using an LLO technique to expose an upper surface of the second semiconductor region 222. Here, the LLO technique refers to a technique of separating the growth substrate 210 from the epitaxially grown layers by irradiating a rear surface of the transparent growth substrate 210 with a UV laser beam having a uniform light output and beam profile, and a single wavelength.

The fourth operation S24 is an operation of forming a mold part 24 surrounding the epitaxial die 200 so that an upper surface of the light-emitting part 220, that is, the upper surface of the second semiconductor region 222, is exposed. At this time, an additional passivation layer 250 may be formed on both side surfaces of the epitaxial die 200 prior to the formation of the mold part, and the mold part 24 may be made of a material that enables LDS or LDI to allow laser drilling in the sixth operation S26 to be described below.

The fifth operation S25 is an operation of forming the second ohmic electrode 240 that is formed to be exposed on an upper surface of the light-emitting part 220 to be electrically connected to the light-emitting part 220. That is, the second ohmic electrode 240 is electrically connected to the light-emitting part 220, i.e., the second semiconductor region 222, and is formed to be exposed on the upper surface of the second semiconductor region 222.

At this time, the upper surface of the second semiconductor region 222 has a nitrogen (N) polar surface, which forms an n-ohmic contact and is electrically connected to the second ohmic electrode 240, and heat treatment at a high temperature of 300° C. or higher is necessarily performed to ensure that the nitrogen (N) polar surface of the second semiconductor region 222 forms an n-ohmic contact with the second ohmic electrode 240.

Meanwhile, in the fifth operation S25, a surface texture pattern of a predetermined shape or an irregular shape may be formed on the upper surface of the light-emitting part 220, i.e., the upper surface of the second semiconductor region 222, of the upside-down epitaxial die 200 to extract as much light generated in the active region 223 into the air as possible.

The sixth operation S26 is an operation of etching the mold part 24 to expose the second electrode pad 21b and forming an extension electrode 23 that electrically connects the second electrode pad 21b to the second ohmic electrode 240. That is, in the sixth operation S26, a through hole H is formed above the second electrode pad 21b using laser drilling, and the extension electrode 23 is formed to extend vertically from an upper portion of the second electrode pad 21b to above the mold part 24 through the through hole H and then be bent toward the second ohmic electrode 240, thereby electrically connecting the second ohmic electrode 240 and the second electrode pad 21b, which is a common negative electrode.

The seventh operation S27 is an operation of forming a black matrix 25 that covers the extension electrode 23 and the mold part 24. The black matrix 25 may be formed using photolithography and spin coating processes, but the present invention is not limited thereto.

Hereinafter, with reference to the accompanying drawings, an epitaxial die 300 for a semiconductor light-emitting device according to a third embodiment of the present invention will be described in detail.

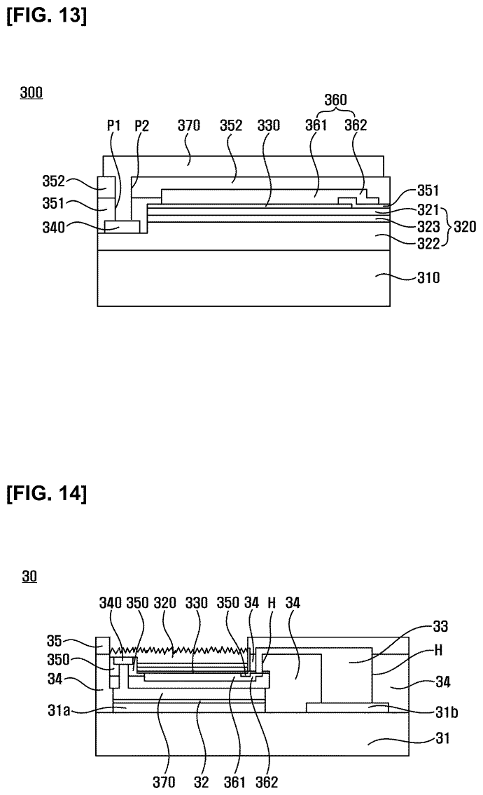

FIG. 13 illustrates an overall view of the epitaxial die for a semiconductor light-emitting device according to the third embodiment of the present invention.

As shown in FIG. 13, the epitaxial die 300 for a semiconductor light-emitting device according to the third embodiment of the present invention includes an initial growth substrate 310, a light-emitting part 320, a first ohmic electrode 330, a second ohmic electrode 340, a first passivation layer 351, a contact electrode 360, a second passivation layer 352, and a bonding pad layer 370.

The initial growth substrate 310 supports the light-emitting part 320, the first ohmic electrode 330, the second ohmic electrode 340, the first passivation layer 351, the contact electrode 360, the second passivation layer 352, and the bonding pad layer 370, and a sapphire initial growth substrate 310 may be used. The light-emitting part 320 to be described below may be epitaxially grown on the initial growth substrate 310.

Meanwhile, in the present invention, the initial growth substrate 310 on which the light-emitting part 320 is grown functions as a final support substrate that supports the light-emitting part 320, the first ohmic electrode 330, the second ohmic electrode 340, the first passivation layer 351, the contact electrode 360, the second passivation layer 352, and the bonding pad layer 370 after the epitaxial die 300 of the present invention is finally completed.

The light-emitting part 320 generates light, and in the present invention, in order to emit blue or green light, binary, ternary, and quaternary compounds such as indium nitride (InN), indium gallium nitride (InGaN), gallium nitride (GaN), aluminum gallium nitride (AlGaN), aluminum nitride (AlN), and aluminum gallium indium nitride (AlGaInN), which are Group III (Al, Ga, and In) nitride semiconductors, can be epitaxially grown on the initial growth substrate 310 by being placed in appropriate positions and sequences.

In particular, in order to emit blue or green light, high-quality indium gallium nitride (InGaN) with a high indium (In) composition, which is a Group III nitride semiconductor, should preferentially be formed on Group III nitride semiconductors composed of gallium nitride (GaN), aluminum gallium nitride (AlGaN), aluminum nitride (AlN), and aluminum gallium indium nitride (AlGaInN), but the present invention is not limited thereto.

More specifically, the light-emitting part 320 includes a first semiconductor region 321 (e.g., a p-type semiconductor region), an active region 323 (e.g., MQWs), and a second semiconductor region 322 (e.g., an n-type semiconductor region), and the light-emitting part 320 may have a structure in which the second semiconductor region 322, the active region 323, and the first semiconductor region 321 are epitaxially grown in this order on the initial growth substrate 310, and ultimately, may have an overall thickness typically ranging from about 5.0 to 8.0 μm, including multiple layers of group III nitrides, but the present invention is not limited thereto.

Each of the first semiconductor region 321, the active region 323, and the second semiconductor region 322 may be formed as either a single layer or multiple layers, and although not shown in the drawing, necessary layers, such as buffer regions a, may be added before epitaxially growing the light-emitting part 320 on the sapphire initial growth substrate 310 to ensure the high quality of the epitaxially grown light-emitting part 320. For example, the buffer regions may include a nucleation layer and a compliant layer composed of an un-doped semiconductor region to relieve stress and improve thin-film quality and typically have a thickness of about 4.0 μm. In addition, when the initial growth substrate 310 is removed using an LLO technique, a sacrificial layer may be provided between the nucleation layer and the un-doped semiconductor region, and a seed layer may function as the sacrificial layer.

The second semiconductor region 322 has a second conductivity type (n-type), and is formed on the initial growth substrate 310. The second semiconductor region 322 may have a thickness of 2.0 to 3.5 μm.

The active region 323 generates light using the recombination of electrons and holes and is formed on the second semiconductor region 322. The active region 323 may have a multi-layer structure primarily composed of indium gallium nitride (InGaN) and gallium nitride (GaN) semiconductors, and may have a thickness of several tens of nanometers (nm).

The first semiconductor region 321 has a first conductivity type (p-type), and is formed on the active region 323. The first semiconductor region 321 may have a multi-layer structure primarily composed of aluminum gallium nitride (AlGaN) and gallium nitride (GaN) semiconductors, have a thickness ranging from several tens of nanometers (nm) to several micrometers (μm), and include a top surface having gallium (Ga) polarity.

That is, the active region 323 is interposed between the first semiconductor region 321 and the second semiconductor region 322, and light is generated when holes in the first semiconductor region 321, which is a p-type semiconductor region, and electrons in the second semiconductor region 322, which is an n-type semiconductor region, recombine in the active region 323.

At this time, one side of the light-emitting part 320 formed on the initial growth substrate 310 may have a shape etched to a predetermined depth (i.e., one side may have a mesa-etched shape), and here, the predetermined depth may refer to a depth up to the second semiconductor region 322, but the present invention is not limited thereto. Meanwhile, the surface of the etched portion of the second semiconductor region 322 of the light-emitting part 320 has gallium (Ga) polarity.

The first ohmic electrode 330 is electrically connected to the first semiconductor region 321 of the light-emitting part 320 and is formed on the first semiconductor region 321 so as to cover and come into surface contact with an upper surface of the first semiconductor region 321. At this time, the first semiconductor region 321 is electrically connected to the first ohmic electrode 330 through a p-ohmic contact.

The second ohmic electrode 340 is electrically connected to the second semiconductor region 322 of the light-emitting part 320 and is formed at an etched portion on one side of the second semiconductor region 322.

The first ohmic electrode 330 and the second ohmic electrode 340 may be basically formed of materials that have high transparency and/or reflectance and excellent electrical conductivity, but the present invention is not limited thereto. The materials of the first ohmic electrode 330 may include optically transparent materials such as indium tin oxide (ITO), zinc oxide (ZnO), indium zinc oxide (IZO), indium gallium zinc oxide (IGZO), and titanium nitride (TiN), and optically reflective materials such as Ag, Al, Rh, Pt, Ni, Pd, Ru, Cu, and Au, may be used alone or in combination with the above-described optically transparent materials. Meanwhile, the materials of the second ohmic electrode 340 may include optically transparent materials such as indium tin oxide (ITO), zinc oxide (ZnO), indium zinc oxide (IZO), indium gallium zinc oxide (IGZO), and titanium nitride (TiN), and metals such as Cr, Ti, Al, V, W, Re, and Au, and may be used alone or in combination with above-described metals.

At this time, as described above, the etched portion of the second semiconductor region 322 has a gallium (Ga) polarity surface, and the gallium (Ga) polarity surface is electrically connected to the second ohmic electrode 340 through an n-ohmic contact.

The first passivation layer 351 covers one side of the first ohmic electrode 330 from the etched portion on one side of the light-emitting part 320 via the second ohmic electrode 340, and covers the other side of the first ohmic electrode 330 from the other side of the light-emitting part 320. The first passivation layer 351 may have a shape that covers each of one side and the other side of the first ohmic electrode 330 and may thus have a shape that exposes a portion of the first ohmic electrode.

The first passivation layer 351 may be implemented with electrically insulating materials, and may include a single layer or multiple layers including at least one material from among silicon oxide, silicon nitride, metallic oxides including Al2O3, and organic insulators.

The contact electrode 360 is electrically connected to the first ohmic electrode 330 and formed on the first ohmic electrode 330 exposed between gaps in the first passivation layer 351. The contact electrode 360 includes a base part 361 and an extension part 362 that is formed to extend from an end portion of the base part to the other side (i.e., the side opposite to where the second ohmic electrode 340 is formed) of the light-emitting part and is placed between the first passivation layer 351 and the second passivation layer 352. At this time, the extension part 362 may be formed to be stepped by being partially bent.

The materials of the contact electrode 360 are not limited as long as they have strong adhesion to the first ohmic electrode 330, but may include Ti, TiN, Cr, CrN, V, VN, NiCr, Al, Rh, Pt, Ni, Pd, Ru, Cu, Ag, Au, and the like.

The second passivation layer 352 covers the first passivation layer 351 and the contact electrode 360, and here, an end portion on the other side (i.e., the side opposite to where the second ohmic electrode 340 is formed) of the contact electrode 360 may be partially etched, and the second passivation layer 352 may cover an end portion on one side of the contact electrode 360 from the etched end portion on the other side of the contact electrode 360 via the contact electrode 360 to prevent the contact electrode 360 from being exposed to the outside. Due to the shape of the second passivation layer 352 that encloses the contact electrode 360, the contact electrode 360 is interposed between the second passivation layer 352 and the first ohmic electrode 330 and thus is not exposed.

The second passivation layer 352 may be implemented with electrically insulating materials, and may include a single layer or multiple layers including at least one material from among silicon oxide, silicon nitride, metallic oxides including Al2O3, and organic insulators.

The bonding pad layer 370 functions as a vertical chip die bonding pad, and is formed on the second passivation layer 352 to be electrically connected to the second ohmic electrode 340. At this time, the bonding pad layer 370 is electrically connected to the second ohmic electrode 340, is exposed to the outside, and functions as a negative electrode.

Meanwhile, a first through hole P1 is formed in the first passivation layer 351 above the second ohmic electrode 340 to expose the second ohmic electrode 340, and a second through hole P2 in communication with the first through hole P1 is formed in the second passivation layer 352. The bonding pad layer 370 can be electrically connected to the second ohmic electrode 340 through the first through hole P1 and the second through hole P2.

The bonding pad layer 370 may basically include low melting point metals and noble metals such as gold (Au), silver (Ag), copper (Cu), and palladium (Pd), but the present invention is not limited thereto. In addition, the low melting point metals of the bonding pad layer 370 may be formed of metals such as In, Sn, Zn, and Pb alone or an alloy including these metals.

Accordingly, in the epitaxial die 300 for a semiconductor light-emitting device according to the third embodiment of the present invention, the contact electrode 360 serving as a positive electrode and the first ohmic electrode 330 are interposed between the second passivation layer 352 and the light-emitting part 320 and thus are not exposed, and only the bonding pad layer 370 functioning as a negative electrode is exposed to the outside.

Hereinafter, with reference to the accompanying drawings, a semiconductor light-emitting device 30 according to the third embodiment of the present invention will be described in detail.

The semiconductor light-emitting device 30 of the present invention may be formed as a COB in which individual chips or epitaxial die units are directly transferred and connected to a substrate (such as a semiconductor wafer, a PCB, or TFT glass) on which circuit wiring and driving element regions are completed, a POB in which package units (including 1, 2, 4, 9, 36, . . . , and n2 chips or epitaxial dies) manufactured using a fan-out package process known in conventional memory semiconductor technology are directly transferred and connected to a substrate on which circuit wiring and driving element regions (such as a semiconductor wafer, a PCB, or TFT glass) are completed, or an interposer using an intermediate temporary substrate on which circuit wiring and driving element regions are not completed, but is not limited thereto, and will be described herein as being formed as the COB type for convenience of description.

FIG. 14 illustrates an overall view of the semiconductor light-emitting device according to the third embodiment of the present invention.

As shown in FIG. 14, the semiconductor light-emitting device 30 according to the third embodiment of the present invention includes a substrate part 31, the epitaxial die 300, a bonding layer 32, an extension electrode 33, a mold part 34, and a black matrix 35.

The substrate part 31 supports the epitaxial die 300 that is bonded thereto, and a first electrode pad 31a and a second electrode pad 31b are each formed on an upper surface of the substrate part 31. The substrate part 31 may refer to a semiconductor wafer, a PCB, TFT glass, an interposer, or the like, but the present invention is not limited thereto.

Further, the first electrode pad 31a may refer to an individual negative electrode, and the second electrode pad 31b may refer to a common positive electrode. For example, after three epitaxial dies 300 emitting blue, green, and red light are respectively placed on three individual negative electrodes and bonded to form a single pixel, each of the epitaxial dies 300 may be electrically connected to the common positive electrode.

The epitaxial die 300 is placed upside down on the first electrode pad 31a of the substrate part 31 so that the bonding pad layer 370 comes into contact with the first electrode pad 31a, and includes a light-emitting part 320, a first ohmic electrode 330, a second ohmic electrode 340, a first passivation layer 351, a contact electrode 360, a second passivation layer 352, and a bonding pad layer 370.

Here, the light-emitting part 320, the first ohmic electrode 330, the second ohmic electrode 340, the first passivation layer 351, the contact electrode 360, the second passivation layer 352, and the bonding pad layer 370 are the same as those of the epitaxial die 300 for the semiconductor light-emitting device according to the third embodiment of the present invention described above, and thus redundant descriptions will be omitted.

Meanwhile, in the upside-down epitaxial die 300, a surface texture pattern of a predetermined shape or an irregular shape may be formed on an upper surface of the light-emitting part 320, i.e., an upper surface of the second semiconductor region 322, in order to extract as much light generated in the active region 323 into the air as possible.

Meanwhile, the light-emitting part 320 is etched on the other side (i.e., the side opposite to where the second ohmic electrode 340 is formed) to expose the first passivation layer 351, and the exposed first passivation layer 351 is partially etched so that a portion of the extension part 362 of the contact electrode 360 may be exposed.

The bonding layer 32 electrically connects the first electrode pad 31a of the substrate part 31 and the bonding pad layer 370 of the epitaxial die 300 by bonding them together, and may include low melting point metals and noble metals such as gold (Au), silver (Ag), copper (Cu), and palladium (Pd) similar to or the same as the bonding pad layer 370 of the epitaxial die 300, but the present invention is not limited thereto.

The extension electrode 33 electrically connects the second electrode pad 31b of the substrate part 31 to the contact electrode 360 of the epitaxial die 300, and is formed to extend vertically from an upper portion of the second electrode pad 31b to above the mold part 34 through a through hole H of the mold part 34, which will be described below, then extend horizontally by being bent toward the contact electrode 360, and finally extend vertically by being bent to come into contact with the exposed extension part 362 of the contact electrode 360.

The extension electrode 33 may be formed of optically transparent and electrically conductive ceramics such as ITO, TiN, carbon nanotubes (CNT), and silver nanowires (Ag nanowires), or low melting point metals and noble metals such as gold (Au), silver (Ag), copper (Cu), and palladium (Pd) similar to or the same as the above-described materials of the bonding layer 32, but the present invention is not limited thereto.

The mold part 34 surrounds and supports the epitaxial die 300 and the extension electrode 33, which are disposed to form a vertical structure, and is formed so that the upper surface of the light-emitting part 320 of the epitaxial die 300 and an upper surface of the extension electrode 33 are exposed. In the mold part 34, a through hole H is formed above the second electrode pad 31b, and a through hole H passing through the first passivation layer 351 is also formed above the contact electrode 360. The extension electrode 33 is electrically connected to the second electrode pad 31b and the contact electrode 360 through the through holes H.

Meanwhile, laser drilling may be used to form the through holes H, and in this case, the mold part 34 may be made of materials that enable LDS or LDI.

The black matrix (BM) 35 covers the exposed upper surfaces of the extension electrode 33 and the mold part 34, and may be formed using photolithography and spin coating processes, but the present invention is not limited thereto.

In addition, the black matrix 35 may be formed of a metal thin film or a carbon-based organic material with an optical density of 3.5 or higher, but the present invention is not limited thereto. More specifically, representative examples thereof include a chromium (Cr) monolayer film, a chromium (Cr)/chromium oxide (CrOx) bilayer film, manganese dioxide (MnO2), an organic black matrix, graphite, and a pigment dispersion composition (prepared by blending a block copolymer resin with pigment-affinity groups such as amino, hydroxyl, and carboxyl groups, with carbon black as a medium, and mixing the blend with a solvent and a dispersing agent).

Hereinafter, with reference to the accompanying drawings, a method (S300) of manufacturing the epitaxial die for a semiconductor light-emitting device according to the third embodiment of the present invention will be described in detail.

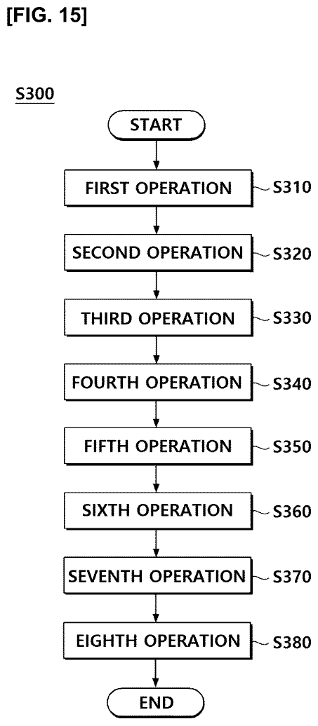

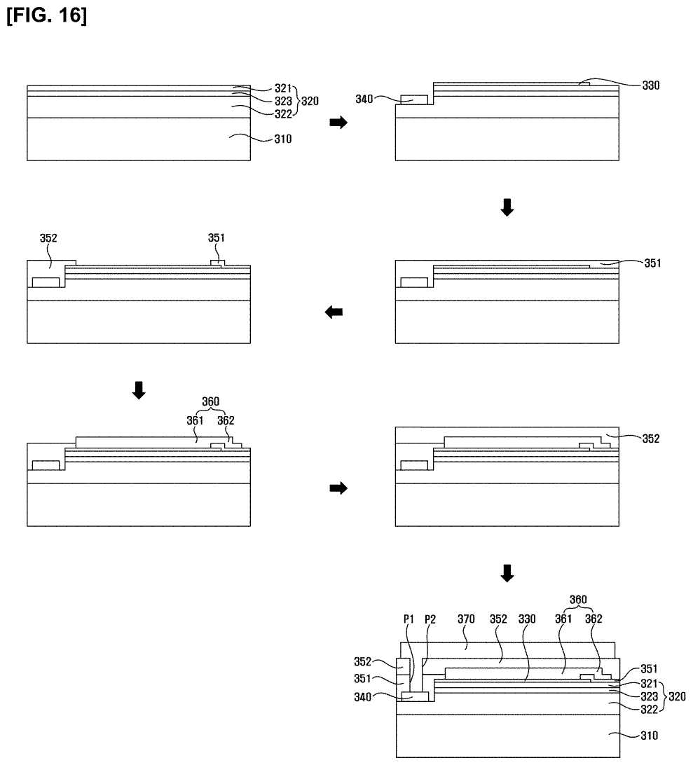

FIG. 15 is a flowchart of the method of manufacturing the epitaxial die for a semiconductor light-emitting device according to the third embodiment of the present invention, and FIG. 16 illustrates a process of manufacturing the epitaxial die for a semiconductor light-emitting device according to the third embodiment of the present invention.

As shown in FIGS. 15 and 16, the method (S300) of manufacturing the epitaxial die for a semiconductor light-emitting device according to the third embodiment of the present invention includes a first operation S310, a second operation S320, a third operation S330, a fourth operation S340, a fifth operation S350, a sixth operation S360, a seventh operation S370, and an eighth operation S380. However, it is of course possible that the order of the processes shown in FIGS. 15 and 16 can be changed.

The first operation S310 is an operation of preparing an initial growth substrate 310. The initial growth substrate 310 is a substrate on which a light-emitting part 320, which will be described below, is epitaxially grown, and supports the light-emitting part 320, a first ohmic electrode 330, a second ohmic electrode 340, a first passivation layer 351, a contact electrode 360, a second passivation layer 352, and a bonding pad layer 370. A sapphire initial growth substrate 310 may be used.

Meanwhile, in the present invention, the initial growth substrate 310 on which the light-emitting part 320 is grown functions as a final support substrate that supports the light-emitting part 320, the first ohmic electrode 330, the second ohmic electrode 340, the first passivation layer 351, the contact electrode 360, the second passivation layer 352, and the bonding pad layer 370 after the epitaxial die 300 of the present invention is finally completed.

The second operation S320 is an operation of forming the light-emitting part 320 on the initial growth substrate 310. That is, more specifically, the light-emitting part 320 includes a first semiconductor region 321 (e.g., a p-type semiconductor region), an active region 323 (e.g., MQWs), and a second semiconductor region 322 (e.g., an n-type semiconductor region), and in the second operation S320, the second semiconductor region 322, the active region 323, and the first semiconductor region 321 are epitaxially grown in this order on the initial growth substrate 310.

The third operation S330 is an operation of forming the first ohmic electrode 330 that is electrically connected to the first semiconductor region 321 by covering so as to come into surface contact with an upper surface of the first semiconductor region 321 of the light-emitting part 320. At this time, heat treatment is selectively performed at a high temperature of 300° C. or higher so that the first semiconductor region 321 forms a p-ohmic contact with the first ohmic electrode 330.

The fourth operation S340 is an operation of etching one side of each of the light-emitting part 320 and the first ohmic electrode 330 to a predetermined depth, and forming the second ohmic electrode 340 in the etched portion.

That is, after etching one side of each of the light-emitting part 320 and the first ohmic electrode 330 to a predetermined depth (the one side may have a mesa-etched shape), the second ohmic electrode 340 is formed on the etched portion on one side of the second semiconductor region 322 of the light-emitting part 320. At this time, the surface of the etched portion of the second semiconductor region 322 has gallium (Ga) polarity, and the gallium (Ga) polarity surface needs to be heat treated at a high temperature of 300° C. or higher to form an n-ohmic contact with the second ohmic electrode 340.

The fifth operation S350 is an operation of forming the first passivation layer 351 that covers the first ohmic electrode 330 from the etched portion of the light-emitting part 320 via the second ohmic electrode 340.

The sixth operation S360 is an operation of etching a portion of the first passivation layer 351 to expose the first ohmic electrode 330 and forming the contact electrode 360 to come into contact with the exposed first ohmic electrode 330. Accordingly, the first passivation layer 351 may have a shape that covers each of one side and the other side of the first ohmic electrode 330.

Meanwhile, the contact electrode 360 includes a base part 361 and an extension part 362, which is formed to extend from an end portion of the base part toward the other side (i.e., the side opposite to where the second ohmic electrode 340 is formed) of the light-emitting part and placed between the first passivation layer 351 and the second passivation layer 352. At this time, the extension part 362 may be formed to be stepped by being partially bent.

The seventh operation S370 is an operation of forming the second passivation layer 352 that covers the first passivation layer 351 and the contact electrode 360. At this time, an end portion on the other side (i.e., the side opposite to where the second ohmic electrode 340 is formed) of the contact electrode 360 may be partially etched, and the second passivation layer 352 may cover an end portion on one side of the contact electrode 360 from the etched end portion on the other side of the contact electrode 360 via the contact electrode 360 so that the contact electrode 360 is not exposed to the outside. Due to the shape of the second passivation layer 352 that encloses the contact electrode 360 in this manner, the contact electrode 360 is interposed between the second passivation layer 352 and the first ohmic electrode 330 and thus is not exposed.

The eighth operation S380 is an operation of etching a portion of each of the first passivation layer 351 and the second passivation layer 352 to expose the second ohmic electrode 340, and forming the bonding pad layer 370 that is electrically connected to the exposed second ohmic electrode 340 and functions as a vertical chip bonding pad. At this time, the bonding pad layer 370 is electrically connected to the second ohmic electrode 340, is exposed to the outside, and functions as a negative electrode.

Meanwhile, a first through hole P1 is formed in the first passivation layer 351 above the second ohmic electrode 340 to expose the second ohmic electrode 340, and a second through hole P2 in communication with the first through hole P1 is formed in the second passivation layer 352. The bonding pad layer 370 can be electrically connected to the second ohmic electrode 340 through the first through hole P1 and the second through hole P2.

After the basic structure of the epitaxial die 300 is formed through the above-described first operation S310 to eighth operation S380, processes such as grinding, dicing, probing, and sorting are performed.

Hereinafter, with reference to the accompanying drawings, a method (S30) of manufacturing the semiconductor light-emitting device according to the third embodiment of the present invention will be described in detail.

The semiconductor light-emitting device of the present invention may be formed as a COB in which individual chips or epitaxial die units are directly transferred and connected to a substrate (such as a semiconductor wafer, a PCB, or TFT glass) on which circuit wiring and driving element regions are completed, a POB in which package units (including 1, 2, 4, 9, 36, . . . , and n2 chips or epitaxial die units) manufactured using a fan-out package process known in conventional memory semiconductor technology are directly transferred and connected to a substrate on which circuit wiring and driving element regions (such as a semiconductor wafer, a PCB, or TFT glass) are completed, or an interposer using an intermediate temporary substrate on which circuit wiring and driving element regions are not completed, but is not limited thereto, and will be described herein as being formed as the COB type for convenience of description.

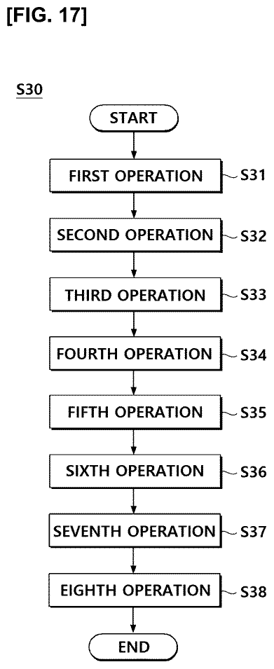

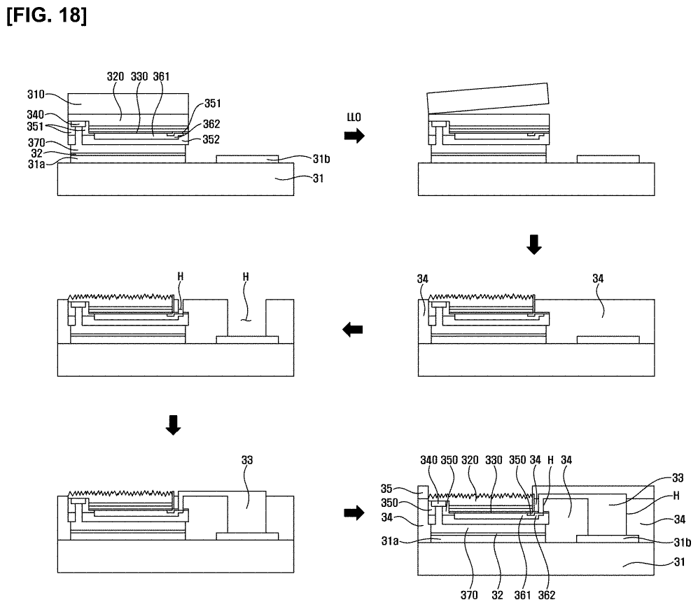

FIG. 17 is a flowchart of the method of manufacturing the semiconductor light-emitting device according to the third embodiment of the present invention, and FIG. 18 illustrates a process of manufacturing the semiconductor light-emitting device according to the third embodiment of the present invention.

As shown in FIGS. 17 and 18, the method (S30) of manufacturing the semiconductor light-emitting device according to the third embodiment of the present invention includes a first operation S31, a second operation S32, a third operation S33, a fourth operation S34, a fifth operation S35, a sixth operation S36, a seventh operation S37, and an eighth operation S38. However, it is of course possible that the order of the processes shown in FIGS. 17 and 18 can be changed.

The first operation S31 is an operation of preparing the epitaxial die 300 for a semiconductor light-emitting device according to the third embodiment of the present invention and a substrate part 31 on which a first electrode pad 31a and a second electrode pad 31b are each formed. The substrate part 31 may refer to a semiconductor wafer, a PCB, TFT glass, an interposer, or the like, but the present invention is not limited thereto.

The second operation S32 is an operation of placing the epitaxial die 300 upside down on the first electrode pad 31a, which is an individual negative electrode, and electrically connecting the first electrode pad 31a and the bonding pad layer 370 by bonding them through a bonding layer 32. At this time, the placement and bonding of the epitaxial die 300 can be accomplished through typical chip die transfer processes such as pick-and-place, roll-to-roll (R2R), and stamps (made from materials such as polydimethylsiloxane (PDMS), silicon (Si), quartz, and glass), which are commonly known tools used in representative processes of massive transfer.

Meanwhile, when it is necessary to achieve objectives such as (1) high precision placement of an epitaxial die 300, (2) an epitaxial die 300 with a ultra-small size of less than 50 μm×50 μm, and (3) an epitaxial die 300 having a self-assembly structure, additional masking media (such as a photoresist, ceramics (like glass, quartz, and alumina), or an invar FMM) or processes may be employed before the placement and bonding of the epitaxial die 300.

The third operation S33 is an operation of separating the initial growth substrate 310 of the epitaxial die 300. At this time, in the third operation S33, the initial growth substrate 310 may be separated from the light-emitting part 320, i.e., the second semiconductor region 322, using an LLO technique to expose an upper surface of the second semiconductor region 322. Here, the LLO technique refers to a technique of separating the initial growth substrate 310 from the epitaxially grown layers by irradiating a rear surface of the transparent growth substrate 310 with a UV laser beam having a uniform light output and beam profile, and a single wavelength.

The fourth operation S34 is an operation of etching the other side (i.e., the side opposite to where the second ohmic electrode 340 is formed) of the light-emitting part 320 so that the first passivation layer 351 is exposed. At this time, a passivation layer may be additionally formed on a side surface of the etched and exposed light-emitting part 320.

The fifth operation S35 is an operation of forming a mold part 34 surrounding the epitaxial die 300 so that an upper surface of the light-emitting part 320, that is, the upper surface of the second semiconductor region 322, is exposed. At this time, the mold part 34 may be made of materials that enable LDS or LDI to allow laser drilling in the sixth operation S36 to be described below.

The sixth operation S36 is an operation of etching the mold part 34 so that the second electrode pad 31b is exposed, and etching the mold part 34 and the first passivation layer 351 so that the contact electrode 360 is exposed. That is, in the sixth operation S36, laser drilling is used to etch the mold part 34 above the second electrode pad 31b to form a through hole H above the second electrode pad 31b, and to etch the first passivation layer 351 and the mold part 34 above the contact electrode 360, which is formed to extend, to form a through hole H above the contact electrode 360.

The seventh operation S37 is an operation of forming an extension electrode 33 that electrically connects the second electrode pad 31b and the exposed contact electrode 360. That is, the extension electrode 33 may have a shape that is formed to extend vertically from an upper portion of the second electrode pad 31b to above the mold part 34 through the through hole H, then be bent horizontally toward the contact electrode 360 and extend further, and finally be bent vertically to come into contact with the exposed contact electrode 360.

The eighth operation S38 is an operation of forming a black matrix 35 that covers the extension electrode 33 and the mold part 34. The black matrix 35 may be formed using photolithography and spin coating processes, but the present invention is not limited thereto.

Hereinafter, with reference to the accompanying drawings, an epitaxial die 400 for a semiconductor light-emitting device according to a fourth embodiment of the present invention will be described in detail.

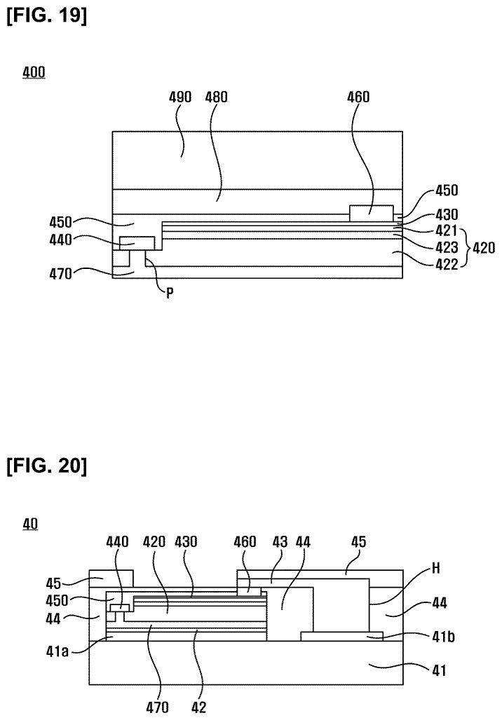

FIG. 19 illustrates an overall view of the epitaxial die for a semiconductor light-emitting device according to the fourth embodiment of the present invention.

As shown in FIG. 19, the epitaxial die 400 for a semiconductor light-emitting device according to the fourth embodiment of the present invention includes a light-emitting part 420, a first ohmic electrode 430, a second ohmic electrode 440, a passivation layer 450, a contact electrode 460, a bonding pad layer 470, a temporary bonding layer 480, and an intermediate temporary substrate 490.

The light-emitting part 420 generates light, and in the present invention, in order to emit blue or green light, binary, ternary, and quaternary compounds such as indium nitride (InN), indium gallium nitride (InGaN), gallium nitride (GaN), aluminum gallium nitride (AlGaN), aluminum nitride (AlN), and aluminum gallium indium nitride (AlGaInN), which are Group III (Al, Ga, and In) nitride semiconductors, can be epitaxially grown on an initial growth substrate 410 by being placed in appropriate positions and sequences (the epitaxial die 400 of the present invention has a structure in which the initial growth substrate 410 is separated after the intermediate temporary substrate 490 is bonded).

In particular, in order to emit blue or green light, high-quality indium gallium nitride (InGaN) with a high indium (In) composition, which is a Group III nitride semiconductor, should preferentially be formed on Group III nitride semiconductors composed of gallium nitride (GaN), aluminum gallium nitride (AlGaN), aluminum nitride (AlN), and aluminum gallium indium nitride (AlGaInN), but the present invention is not limited thereto.

More specifically, the light-emitting part 420 includes a first semiconductor region 421 (e.g., a p-type semiconductor region), an active region 423 (e.g., MQWs), and a second semiconductor region 422 (e.g., an n-type semiconductor region), and the light-emitting part 420 may have a structure in which the second semiconductor region 422, the active region 423, and the first semiconductor region 421 are epitaxially grown in this order on the initial growth substrate, and ultimately, may have an overall thickness typically ranging from about 5.0 to 8.0 μm, including multiple layers of group III nitrides, but the present invention is not limited thereto.

Each of the first semiconductor region 421, the active region 423, and the second semiconductor region 422 may be formed as either a single layer or multiple layers, and although not shown in the drawing, necessary layers, such as buffer regions, may be added before epitaxially growing the light-emitting part 420 on the sapphire initial growth substrate to ensure the high quality of the epitaxially grown light-emitting part 420. For example, the buffer regions may include a nucleation layer and a compliant layer composed of an un-doped semiconductor region to relieve stress and improve thin-film quality and typically have a thickness of about 4.0 μm. In addition, when the initial growth substrate is removed using an LLO technique, a sacrificial layer may be provided between the nucleation layer and the un-doped semiconductor region, and a seed layer may function as the sacrificial layer.

The second semiconductor region 422 has a second conductivity type (n-type), and is formed on the initial growth substrate. The second semiconductor region 422 may have a thickness of 2.0 to 3.5 μm.

The active region 423 generates light using the recombination of electrons and holes and is formed on the second semiconductor region 422. The active region 423 may have a multi-layer structure primarily composed of indium gallium nitride (InGaN) and gallium nitride (GaN) semiconductors, and may have a thickness of several tens of nanometers (nm).

The first semiconductor region 421 has a first conductivity type (p-type), and is formed on the active region 423. The first semiconductor region 421 may have a multi-layer structure primarily composed of aluminum gallium nitride (AlGaN) and gallium nitride (GaN) semiconductors, have a thickness ranging from several tens of nanometers (nm) to several micrometers (μm), and include a top surface having gallium (Ga) polarity.

That is, the active region 423 is interposed between the first semiconductor region 421 and the second semiconductor region 422, and light is generated when holes in the first semiconductor region 421, which is a p-type semiconductor region, and electrons in the second semiconductor region 422, which is an n-type semiconductor region, recombine in the active region 423.

Meanwhile, the light-emitting part 420, which is formed by epitaxially growing the second semiconductor region 422, the active region 423, and the first semiconductor region 421 in this order on the initial growth substrate 410, may have a structure in which the first semiconductor region 421, the active region 423, and the second semiconductor region 422 are stacked in this order on the intermediate temporary substrate 490 after the first semiconductor region 421 is bonded to the intermediate temporary substrate 490 through the temporary bonding layer 480.

At this time, one side of the light-emitting part 420 formed on the initial growth substrate 410 may have a shape etched to a predetermined depth (i.e., one side may have a mesa-etched shape), and here, the predetermined depth may refer to a depth up to the second semiconductor region 422, but the present invention is not limited thereto. Meanwhile, the surface of the etched portion of the second semiconductor region 422 of the light-emitting part 420 has gallium (Ga) polarity.

The first ohmic electrode 430 is electrically connected to the first semiconductor region 421 of the light-emitting part 420 and is formed on the first semiconductor region 421 so as to cover and come into surface contact with an upper surface of the first semiconductor region 421. At this time, the first semiconductor region 421 is electrically connected to the first ohmic electrode 430 through a p-ohmic contact.

The second ohmic electrode 440 is electrically connected to the second semiconductor region 422 of the light-emitting part 420 and is formed at an etched portion on one side of the second semiconductor region 422.

The first ohmic electrode 430 and the second ohmic electrode 440 may each be basically formed of materials that have high transparency and/or reflectance and excellent electrical conductivity, but the present invention is not limited thereto. The first ohmic electrode 430 may be made of materials including indium tin oxide (ITO), zinc oxide (ZnO), indium zinc oxide (IZO), indium gallium zinc oxide (IGZO), titanium nitride (TiN), Ni (O)—Au, Ni (O)—Ag, and the like. Meanwhile, the materials of the second ohmic electrode 440 may include optically transparent materials such as indium tin oxide (ITO), zinc oxide (ZnO), indium zinc oxide (IZO), indium gallium zinc oxide (IGZO), and titanium nitride (TiN), and metals such as Cr, Ti, Al, V, W, Re, and Au, and may be used alone or in combination with the above-described metals.

At this time, as described above, the etched portion of the second semiconductor region 422 has a gallium (Ga) polarity surface, and the gallium (Ga) polarity surface is electrically connected to the second ohmic electrode 440 through an n-ohmic contact.

The passivation layer 450 covers the first ohmic electrode 430 from the etched portion on one side of the light-emitting part 420 via the second ohmic electrode 440, and the other side (i.e., the side opposite to where the second ohmic electrode 440 is formed) of the light-emitting part 420 is partially etched to expose a portion of the first ohmic electrode 430.

The passivation layer 450 may be implemented with electrically insulating materials, and may include a single layer or multiple layers including at least one material from among silicon oxide, silicon nitride, metallic oxides including Al2O3, and organic insulators.

The contact electrode 460 is electrically connected to the first ohmic electrode 430 and is formed on the first ohmic electrode 430, which is exposed by partially etching the other side (i.e., the side opposite to where the second ohmic electrode 440 is formed) of the passivation layer 450.

The materials of the contact electrode 460 are not limited as long as they have strong adhesion to the first ohmic electrode 430, but may include Ti, TiN, Cr, CrN, V, VN, NiCr, Al, Rh, Pt, Ni, Pd, Ru, Cu, Ag, Au, and the like.

The temporary bonding layer 480 bonds the passivation layer 450, in which the contact electrode 460 is exposed, to the intermediate temporary substrate 490, and is formed above the passivation layer 450 and the contact electrode 460. Due to the shape of the temporary bonding layer 480 that encloses the contact electrode 460, the contact electrode 460 is interposed between the temporary bonding layer 480 and the first ohmic electrode 430 and thus is not exposed.

The temporary bonding layer 480 may include materials such as benzocyclobutene (BCB), SU-8 polymer, flowable oxides (FOx) such as spin-on-glass (SOG) and hydrogen silsesquioxane (HSQ), and alloys including low melting point metals (e.g., In, Sn, and Zn) and noble metals (e.g., Au, Ag, Cu, and Pd).

The intermediate temporary substrate 490 is bonded to the passivation layer 450 by the temporary bonding layer 480 to support the light-emitting part 420, the first ohmic electrode 430, the second ohmic electrode 440, the passivation layer 450, the contact electrode 460, and the bonding pad layer 470 to be described below, and it is preferable that the intermediate temporary substrate 490 is formed of a material that has a thermal expansion coefficient equal or similar to that of the initial growth substrate 410, and is simultaneously optically transparent, as long as the difference in thermal expansion coefficient does not exceed 2 ppm. The most preferable materials for the intermediate temporary substrate 490 that meet these requirements include sapphire, which is used for the initial growth substrate 410, or glass that has been adjusted to have a difference in thermal expansion coefficient of 2 ppm or lower from the initial growth substrate 410.

Meanwhile, in the present invention, the intermediate temporary substrate 490 functions as a final support substrate that supports the light-emitting part 420, the first ohmic electrode 430, the second ohmic electrode 440, the passivation layer 450, the contact electrode 460, and the bonding pad layer 470 to be described below after the epitaxial die 400 of the present invention is finally completed. At this time, it is preferable that an LLO sacrificial separation layer (not shown), which is a functional material that can be easily separated and removed by an LLO technique in the process of a third operation of a method (S40) of manufacturing the semiconductor light-emitting device, which will be described below, is formed between the intermediate temporary substrate 490 and the temporary bonding layer 480. The above-described LLO sacrificial separation layer (not shown) may be made of materials such as ZnO, ITO, IZO, IGO, IGZO, InGaN, InGaON, GaON, TiN, SiO2, SiNx, and the like.

The bonding pad layer 470 functions as a vertical chip die bonding pad, and is formed on a lower surface of the light-emitting part 420 to be electrically connected to the second ohmic electrode 440. At this time, the bonding pad layer 470 is electrically connected to the second ohmic electrode 440, is exposed to the outside, and functions as a negative electrode.

Meanwhile, a through hole P is formed below the light-emitting part 420 to expose the second ohmic electrode 440, and through the through hole P, the bonding pad layer 470 may be electrically connected to the second ohmic electrode 440.

Meanwhile, it is preferable that the bonding pad layer 470 basically includes three regions (not shown). A first region may include transparent electrically conductive materials (i.e., ITO, IZO, ZnO, IGZO, and TiN) with strong adhesion to the light-emitting part 420. A second region may include highly reflective materials (i.e., Al, Ag, AgCu, Rh, Pt, Ni, and Pd). A third region may include low melting point metals and noble metals such as gold (Au), silver (Ag), copper (Cu), and palladium (Pd), but the present invention is not limited thereto. In addition, the low melting point metals of the bonding pad layer 470 may be formed of metals such as In, Sn, Zn, and Pb alone or an alloy including these metals.

Furthermore, although not shown in the drawing, before forming the bonding pad layer 470 on the lower surface of the light-emitting part 420, a surface texture pattern with a predetermined shape or an irregular shape may be formed on a lower surface of the second semiconductor region 422 to extract as much light generated in the active region 423 into the air as possible.

Accordingly, in the epitaxial die 400 for a semiconductor light-emitting device according to the fourth embodiment of the present invention, the contact electrode 460 serving as a positive electrode and the first ohmic electrode 430 are interposed between the temporary bonding layer 480 and the light-emitting part 420 and thus are not exposed, and only the bonding pad layer 470 functioning as a negative electrode is exposed to the outside.

Hereinafter, with reference to the accompanying drawings, a semiconductor light-emitting device 40 according to the fourth embodiment of the present invention will be described in detail.

The semiconductor light-emitting device 40 of the present invention may be formed as a COB in which individual chips or epitaxial die units are directly transferred and connected to a substrate (such as a semiconductor wafer, a PCB, or TFT glass) on which circuit wiring and driving element regions are completed, a POB in which package units (including 1, 2, 4, 9, 46, . . . , and n2 chips or epitaxial die units) manufactured using a fan-out package process known in conventional memory semiconductor technology are directly transferred and connected to a substrate on which circuit wiring and driving element regions (such as a semiconductor wafer, a PCB, or TFT glass) are completed, or an interposer using an intermediate temporary substrate 490 on which circuit wiring and driving element regions are not completed, but is not limited thereto, and will be described herein as being formed as the COB type for convenience of description.

FIG. 20 illustrates an overall view of the semiconductor light-emitting device according to the fourth embodiment of the present invention.

As shown in FIG. 20, the semiconductor light-emitting device 40 according to the fourth embodiment of the present invention includes a substrate part 41, the epitaxial die 400, a bonding layer 42, an extension electrode 43, a mold part 44, and a black matrix 45.

The substrate part 41 supports the epitaxial die 400 that is bonded thereto, and a first electrode pad 41a and a second electrode pad 41b are each formed on an upper surface of the substrate part 41. The substrate part 41 may refer to a semiconductor wafer, a PCB, TFT glass, an interposer, or the like, but the present invention is not limited thereto.

Further, the first electrode pad 41a may refer to an individual negative electrode, and the second electrode pad 41b may refer to a common positive electrode. For example, after three epitaxial dies 400 emitting blue, green, and red light are respectively placed on three individual negative electrodes and bonded to form a single pixel, each of the epitaxial dies 400 may be electrically connected to the common positive electrode.

The epitaxial die 400 is placed on the first electrode pad 41a of the substrate part 41 so that a bonding pad layer 470 comes into contact with the first electrode pad 41a, and includes a light-emitting part 420, a first ohmic electrode 430, a second ohmic electrode 440, a passivation layer 450, a contact electrode 460, and a bonding pad layer 470.

Here, the light-emitting part 420, the first ohmic electrode 430, the second ohmic electrode 440, the passivation layer 450, the contact electrode 460, and the bonding pad layer 470 are the same as those of the above-described epitaxial die 400 for a semiconductor light-emitting device according to the fourth embodiment of the present invention, and thus redundant descriptions will be omitted.

Meanwhile, after the intermediate temporary substrate 490 is separated, the LLO sacrificial separation layer (not shown) and the temporary bonding layer 480 are etched and removed, so that the contact electrode 460 may be exposed.

The bonding layer 42 electrically connects the first electrode pad 41a of the substrate part 41 and the bonding pad layer 470 of the epitaxial die 400 by bonding them together, and may include low melting point metals and noble metals such as gold (Au), silver (Ag), copper (Cu), and palladium (Pd) similar to or the same as the bonding pad layer 470 of the epitaxial die 400, but the present invention is not limited thereto.

The extension electrode 43 electrically connects the second electrode pad 41b of the substrate part 41 to the contact electrode 460 of the epitaxial die 400, and is formed to extend vertically from an upper portion of the second electrode pad 41b to above the mold part 44 through a through hole H of the mold part 44, which will be described below, and then extend horizontally by being bent toward the contact electrode 460 to come into contact with and be electrically connected to the contact electrode 460.

The extension electrode 43 may be formed of optically transparent and electrically conductive ceramics such as ITO, TiN, carbon nanotubes (CNT), and silver nanowires (Ag nanowires), or low melting point metals and noble metals such as gold (Au), silver (Ag), copper (Cu), and palladium (Pd) similar to or the same as the above-described materials of the bonding layer 42, but the present invention is not limited thereto.

The mold part 44 surrounds and supports the epitaxial die 400 and the extension electrode 43, which are disposed to form a vertical structure, and is formed so that an upper surface of the extension electrode 43 is exposed. In the mold part 44, the through hole H is formed above the second electrode pad 41b, and the extension electrode 43 is electrically connected to the second electrode pad 41b and the contact electrode 460 through the through hole H.

Meanwhile, laser drilling may be used to form the through holes H, and in this case, the mold part 44 may be made of materials that enable LDS or LDI.

The black matrix (BM) 45 covers the exposed upper surfaces of the extension electrode 43 and the mold part 44, and may be formed using photolithography and spin coating processes, but the present invention is not limited thereto.

In addition, the black matrix 45 may be formed of a metal thin film or a carbon-based organic material with an optical density of 3.5 or higher, but the present invention is not limited thereto. More specifically, representative examples thereof include a chromium (Cr) monolayer film, a chromium (Cr)/chromium oxide (CrOx) bilayer film, manganese dioxide (MnO2), an organic black matrix, graphite, and a pigment dispersion composition (prepared by blending a block copolymer resin with pigment-affinity groups such as amino, hydroxyl, and carboxyl groups, with carbon black as a medium, and mixing the blend with a solvent and a dispersing agent).

Hereinafter, with reference to the accompanying drawings, a method (S400) of manufacturing the epitaxial die for a semiconductor light-emitting device according to the fourth embodiment of the present invention will be described in detail.

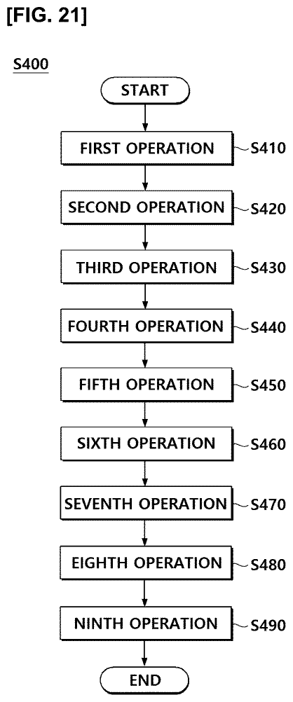

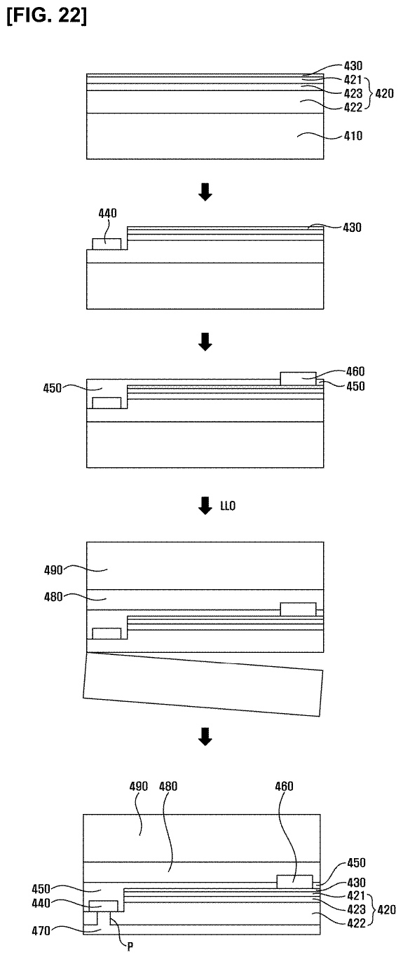

FIG. 21 is a flowchart of the method of manufacturing the epitaxial die for a semiconductor light-emitting device according to the fourth embodiment of the present invention, and FIG. 22 illustrates a process of manufacturing the epitaxial die for a semiconductor light-emitting device according to the fourth embodiment of the present invention.

As shown in FIGS. 21 and 22, the method (S400) of manufacturing the epitaxial die for a semiconductor light-emitting device according to the fourth embodiment of the present invention includes a first operation S410, a second operation S420, a third operation S430, a fourth operation S440, a fifth operation S450, a sixth operation S460, a seventh operation S470, an eighth operation S480, and a ninth operation S490. However, it is of course possible that the order of the processes shown in FIGS. 21 and 22 can be changed.

The first operation S410 is an operation of preparing an initial growth substrate 410 and an intermediate temporary substrate 490. The initial growth substrate 410 is a substrate on which a light-emitting part 420 to be described below is epitaxially grown and a sapphire initial growth substrate 410.

The intermediate temporary substrate 490 is bonded to a passivation layer 450 by a temporary bonding layer 480 to be described below and supports the light-emitting part 420, a first ohmic electrode 430, a second ohmic electrode 440, a passivation layer 450, a contact electrode 460, and a bonding pad layer 470 to be described below, and may include sapphire, which is used as the initial growth substrate 410, or glass that has been adjusted to have a difference in thermal expansion coefficient of 2 ppm or lower from the initial growth substrate 410. Basically, before forming the temporary bonding layer 480, an LLO sacrificial separation layer (not shown) may be formed on the intermediate temporary substrate 490. The above-described LLO sacrificial separation layer (not shown) may be made of materials such as ZnO, ITO, IZO, IGO, IGZO, InGaN, InGaON, GaON, TIN, SiO2, SiNx, and the like.

Meanwhile, in the present invention, after the epitaxial die 400 of the present invention is finally completed, the intermediate temporary substrate 490 functions as a final support substrate that supports the light-emitting part 420, the first ohmic electrode 430, the second ohmic electrode 440, the passivation layer 450, the contact electrode 460, and the bonding pad layer 470.

The second operation S420 is an operation of forming the light-emitting part 420 on the initial growth substrate 410. That is, more specifically, the light-emitting part 420 includes a first semiconductor region 421 (e.g., a p-type semiconductor region), an active region 423 (e.g., MQWs), and a second semiconductor region 422 (e.g., an n-type semiconductor region), and in the second operation S420, the second semiconductor region 422, the active region 423, and the first semiconductor region 421 are epitaxially grown in this order on the initial growth substrate 410.

The third operation S430 is an operation of forming the first ohmic electrode 430 that is electrically connected to the first semiconductor region 421 by covering so as to come into surface contact with an upper surface of the first semiconductor region 421 of the light-emitting part 420. At this time, heat treatment is selectively performed at a high temperature of 300° C. or higher so that the first semiconductor region 421 forms a p-ohmic contact with the first ohmic electrode 430.

The fourth operation S440 is an operation of etching one side of each of the light-emitting part 420 and the first ohmic electrode 430 to a predetermined depth, and forming the second ohmic electrode 440 in the etched portion.

That is, after etching one side of each of the light-emitting part 420 and the first ohmic electrode 430 to a predetermined depth (the one side may have a mesa-etched shape), the second ohmic electrode 440 is formed on the etched portion on one side of the second semiconductor region 422 of the light-emitting part 420. At this time, the surface of the etched portion of the second semiconductor region 422 has gallium (Ga) polarity, and the gallium (Ga) polarity surface needs to be heat treated at a high temperature of 300° C. or higher to form an n-ohmic contact with the second ohmic electrode 440.

The fifth operation S450 is an operation of forming the passivation layer 450 that covers the first ohmic electrode 430 from the etched portion of the light-emitting part 420 via the second ohmic electrode 440.

The sixth operation S460 is an operation of etching a portion of the passivation layer 450 to expose the first ohmic electrode 430 and forming the contact electrode 460 to come into contact with the exposed first ohmic electrode 430. At this time, the contact electrode 460 may be formed on a side opposite to where the second ohmic electrode 440 is formed.

The seventh operation S470 is an operation of bonding the intermediate temporary substrate 490 and the passivation layer 450, in which the contact electrode 460 is exposed, through the temporary bonding layer 480. Due to the shape of the temporary bonding layer 480 that encloses the contact electrode 460, the contact electrode 460 is interposed between the temporary bonding layer 480 and the first ohmic electrode 430 and thus is not exposed.

The eighth operation S480 is an operation of separating the initial growth substrate 410. At this time, in the seventh operation S470, the initial growth substrate 410 may be separated from the light-emitting part 420, i.e., the second semiconductor region 422, using an LLO technique to expose an upper surface of the second semiconductor region 422. Here, the LLO technique refers to a technique of separating the initial growth substrate 410 from the epitaxially grown layers by irradiating a rear surface of the transparent growth substrate 410 with a UV laser beam having a uniform light output and beam profile, and a single wavelength.

The ninth operation S490 is an operation of etching a portion of the light-emitting part 420 to expose the second ohmic electrode 440 and forming the bonding pad layer 470, which is electrically connected to the exposed second ohmic electrode 440 and functions as a vertical chip bonding pad. At this time, the bonding pad layer 470 is electrically connected to the second ohmic electrode 440 through an n-ohmic contact and is exposed to the outside, thereby functioning as a negative electrode.

Meanwhile, in the light-emitting part 420, a through hole P is formed below the second ohmic electrode 440 to expose the second ohmic electrode 440, and through the through hole P, the bonding pad layer 470 may be electrically connected to the second ohmic electrode 440.

After the basic structure of the epitaxial die 400 is formed through the above-described first operation S410 to ninth operation S490, processes such as grinding, dicing, probing, and sorting are performed.

Hereinafter, with reference to the accompanying drawings, a method (S40) of manufacturing the semiconductor light-emitting device according to the fourth embodiment of the present invention will be described in detail.

The semiconductor light-emitting device of the present invention may be formed as a COB in which individual chips or epitaxial die units are directly transferred and connected to a substrate (such as a semiconductor wafer, a PCB, or TFT glass) on which circuit wiring and driving element regions are completed, a POB in which package units (including 1, 2, 4, 9, 46, . . . , and n2 chips or epitaxial die units) manufactured using a fan-out package process known in conventional memory semiconductor technology are directly transferred and connected to a substrate on which circuit wiring and driving element regions (such as a semiconductor wafer, a PCB, or TFT glass) are completed, or an interposer using an intermediate temporary substrate 490 on which circuit wiring and driving element regions are not completed, but is not limited thereto, and will be described herein as being formed as the COB type for convenience of description.

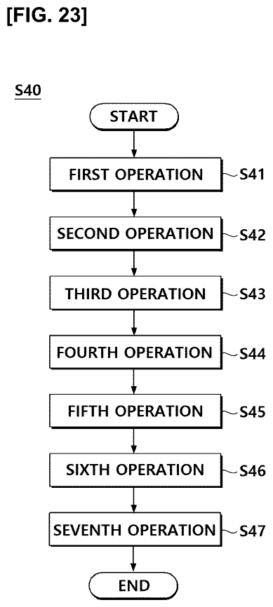

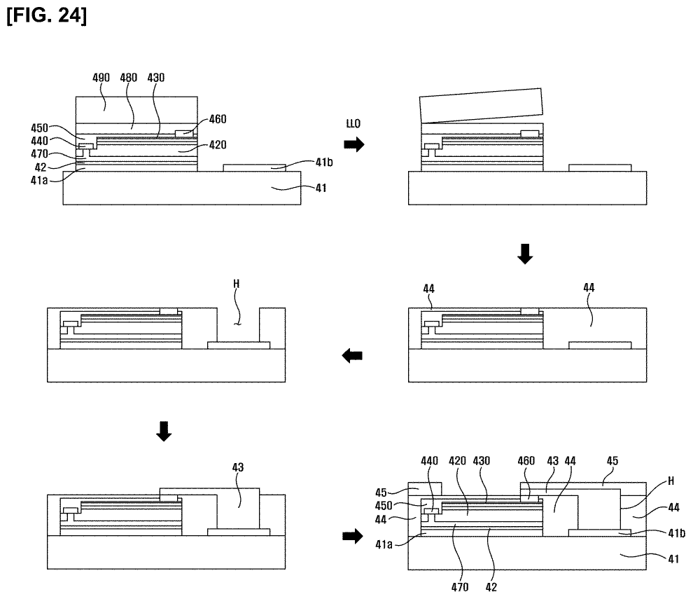

FIG. 23 is a flowchart of the method of manufacturing the semiconductor light-emitting device according to the fourth embodiment of the present invention, and FIG. 24 illustrates a process of manufacturing the semiconductor light-emitting device according to the fourth embodiment of the present invention.

As shown in FIGS. 23 and 24, the method (S40) of manufacturing the semiconductor light-emitting device according to the fourth embodiment of the present invention includes a first operation S41, a second operation S42, a third operation S43, a fourth operation S44, a fifth operation S45, a sixth operation S46, and a seventh operation S47. However, it is of course possible that the order of the processes shown in FIGS. 23 and 24 can be changed.

The first operation S41 is an operation of preparing the epitaxial die 400 for a semiconductor light-emitting device according to the fourth embodiment of the present invention and a substrate part 41 on which a first electrode pad 41a and a second electrode pad 41b are each formed. The substrate part 41 may refer to a semiconductor wafer, a PCB, TFT glass, an interposer, or the like, but the present invention is not limited thereto.

The second operation S42 is an operation of placing the epitaxial die 400 on the first electrode pad 41a, which is an individual negative electrode, and electrically connecting the first electrode pad 41a and the bonding pad layer 470 by bonding them through a bonding layer 42. At this time, the placement and bonding of the epitaxial die 400 can be accomplished through typical chip die transfer processes such as pick-and-place, roll-to-roll (R2R), and stamps (made from materials such as polydimethylsiloxane (PDMS), silicon (Si), quartz, and glass), which are commonly known tools used in representative processes of massive transfer.

Meanwhile, when it is necessary to achieve objectives such as (1) high precision placement of an epitaxial die 400, (2) an epitaxial die 400 with a ultra-small size of less than 50 μm×50 μm, and (3) an epitaxial die 400 having a self-assembly structure, additional masking media (such as a photoresist, ceramics (like glass, quartz, and alumina), or an invar FMM) or processes may be employed before the placement and bonding of the epitaxial die 400.

The third operation S43 is an operation of separating the intermediate temporary substrate 490 of the epitaxial die 400, and etching the LLO sacrificial separation layer (not shown) and the temporary bonding layer 480 to expose the contact electrode 460. At this time, the third operation S43 may separate the intermediate temporary substrate 490 from the temporary bonding layer 480 using an LLO technique. Here, the LLO technique refers to a technique of separating the intermediate temporary substrate 490 from the temporary bonding layer 480 by irradiating a rear surface of the transparent intermediate temporary substrate 490 with a UV laser beam having a uniform output and beam profile, and a single wavelength.

The fourth operation S44 is an operation of forming a mold part 44 surrounding the epitaxial die 400 so that the contact electrode 460 is exposed. At this time, the mold part 44 may be made of materials that enable LDS or LDI to allow laser drilling in the fifth operation S45 to be described below.

The fifth operation S45 is an operation of etching the mold part 44 to expose the second electrode pad 41b. That is, in the fifth operation S45, a through hole H is formed above the second electrode pad 41b by etching the mold part 44 above the second electrode pad 41b using laser drilling.

The sixth operation S46 is an operation of forming an extension electrode 43 that electrically connects the second electrode pad 41b and the exposed contact electrode 460. That is, the extension electrode 43 is formed to extend vertically from an upper portion of the second electrode pad 41b to above the mold part 44 through the through hole H, and then extend horizontally by being bent toward the contact electrode 460 to come into contact with and be electrically connected to the contact electrode 460.

The seventh operation S47 is an operation of forming a black matrix 45 that covers the extension electrode 43 and the mold part 44. The black matrix 45 may be formed using photolithography and spin coating processes, but the present invention is not limited thereto.

Hereinafter, with reference to the accompanying drawings, an epitaxial die 500 for a semiconductor light-emitting device according to a fifth embodiment of the present invention will be described in detail.

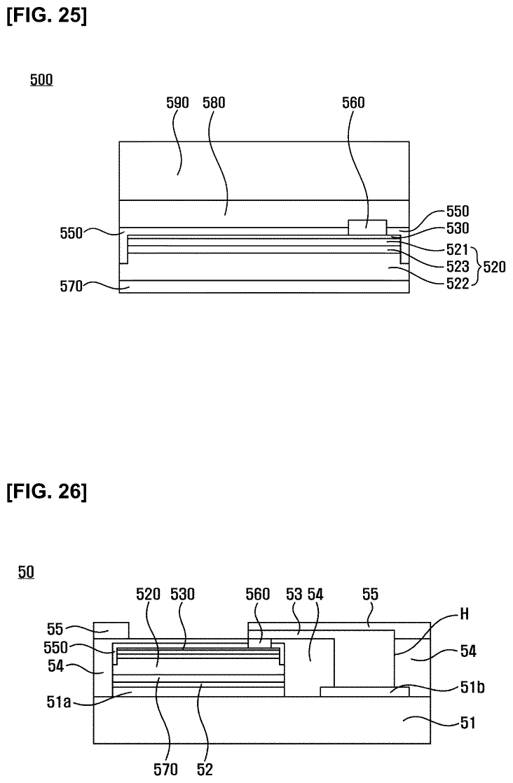

FIG. 25 illustrates an overall view of the epitaxial die for a semiconductor light-emitting device according to the fifth embodiment of the present invention.

As shown in FIG. 25, the epitaxial die 500 for a semiconductor light-emitting device according to the fifth embodiment of the present invention includes a light-emitting part 520, a first ohmic electrode 530, a passivation layer 550, a contact electrode 560, a bonding pad layer 570, a temporary bonding layer 580, and an intermediate temporary substrate 590.

The light-emitting part 520 generates light, and in the present invention, in order to emit blue or green light, binary, ternary, and quaternary compounds such as indium nitride (InN), indium gallium nitride (InGaN), gallium nitride (GaN), aluminum gallium nitride (AlGaN), aluminum nitride (AlN), and aluminum gallium indium nitride (AlGaInN), which are Group III (Al, Ga, and In) nitride semiconductors, can be epitaxially grown on an initial growth substrate 510 by being placed in appropriate positions and sequences (the epitaxial die 500 of the present invention has a structure in which the initial growth substrate 510 is separated after the intermediate temporary substrate 590 is bonded).

In particular, in order to emit blue or green light, high-quality indium gallium nitride (InGaN) with a high indium (In) composition, which is a Group III nitride semiconductor, should preferentially be formed on Group III nitride semiconductors composed of gallium nitride (GaN), aluminum gallium nitride (AlGaN), aluminum nitride (AlN), and aluminum gallium indium nitride (AlGaInN), but the present invention is not limited thereto.

More specifically, the light-emitting part 520 includes a first semiconductor region 521 (e.g., a p-type semiconductor region), an active region 523 (e.g., MQWs), and a second semiconductor region 522 (e.g., an n-type semiconductor region), and the light-emitting part 520 may have a structure in which the second semiconductor region 522, the active region 523, and the first semiconductor region 521 are epitaxially grown in this order on the initial growth substrate, and ultimately, may have an overall thickness typically ranging from about 5.0 to 8.0 μm, including multiple layers of group III nitrides, but the present invention is not limited thereto.

Each of the first semiconductor region 521, the active region 523, and the second semiconductor region 522 may be formed as either a single layer or multiple layers, and although not shown in the drawing, necessary layers, such as buffer regions, may be added before epitaxially growing the light-emitting part 520 on the sapphire initial growth substrate 510 to ensure the high quality of the epitaxially grown light-emitting part 520. For example, the buffer regions may include a nucleation layer and a compliant layer composed of an un-doped semiconductor region to relieve stress and improve thin-film quality and typically have a thickness of about 4.0 μm. In addition, when the initial growth substrate 510 is removed using an LLO technique, a sacrificial layer may be provided between the nucleation layer and the un-doped semiconductor region, and a seed layer may function as the sacrificial layer.

The second semiconductor region 522 has a second conductivity type (n-type), and is formed on the initial growth substrate 510. The second semiconductor region 522 may have a thickness of 2.0 to 3.5 μm.

The active region 523 generates light using the recombination of electrons and holes and is formed on the second semiconductor region 522. The active region 523 may have a multi-layer structure primarily composed of indium gallium nitride (InGaN) and gallium nitride (GaN) semiconductors, and may have a thickness of several tens of nanometers (nm).

The first semiconductor region 521 has a first conductivity type (p-type), and is formed on the active region 523. The first semiconductor region 521 may have a multi-layer structure primarily composed of aluminum gallium nitride (AlGaN) and gallium nitride (GaN) semiconductors, have a thickness ranging from several tens of nanometers (nm) to several micrometers (μm), and include a top surface having gallium (Ga) polarity.

That is, the active region 523 is interposed between the first semiconductor region 521 and the second semiconductor region 522, and light is generated when holes in the first semiconductor region 521, which is a p-type semiconductor region, and electrons in the second semiconductor region 522, which is an n-type semiconductor region, recombine in the active region 523.

Meanwhile, the light-emitting part 520, which is formed by epitaxially growing the second semiconductor region 522, the active region 523, and the first semiconductor region 521 in this order on the initial growth substrate 510, may have a structure in which the first semiconductor region 521, the active region 523, and the second semiconductor region 522 are stacked in this order on the intermediate temporary substrate 590 after the first semiconductor region 521 is bonded to the intermediate temporary substrate 590 through the temporary bonding layer 580.

At this time, both sides of the light-emitting part 520 formed on the initial growth substrate 510 may have a shape etched to a predetermined depth, and the predetermined depth may refer to a depth up to the second semiconductor region 522, but the present invention is not limited thereto.

The first ohmic electrode 530 is electrically connected to the first semiconductor region 521 of the light-emitting part 520 and is formed on the first semiconductor region 521 so as to cover and come into surface contact with an upper surface of the first semiconductor region 521. At this time, the first semiconductor region 521 is electrically connected to the first ohmic electrode 530 through a p-ohmic contact.

This first ohmic electrode 530 may be basically formed of a material with high transparency and excellent electrical conductivity, but the present invention is not limited thereto. The first ohmic electrode 530 may be made of optically transparent materials such as indium tin oxide (ITO), zinc oxide (ZnO), indium zinc oxide (IZO), indium gallium zinc oxide (IGZO), titanium nitride (TiN), Ni (O)—Au, Ni (O)—Ag, and the like.

The passivation layer 550 covers the first ohmic electrode 530 from the etched portions on both sides of the light-emitting part 520, and is partially etched to expose a portion of the first ohmic electrode 530.

The passivation layer 550 may be implemented with electrically insulating materials, and may include a single layer or multiple layers including at least one material from among silicon oxide, silicon nitride, metallic oxides including Al2O3, and organic insulators.

The contact electrode 560 is electrically connected to the first ohmic electrode 530 and is formed on the first ohmic electrode 530 exposed by etching a portion of the passivation layer 550.

The materials of the contact electrode 560 are not limited as long as they have strong adhesion to the first ohmic electrode 530, but may include Ti, TiN, Cr, CrN, V, VN, NiCr, Al, Rh, Pt, Ni, Pd, Ru, Cu, Ag, Au, and the like.

The temporary bonding layer 580 bonds the passivation layer 550, in which the contact electrode 560 is exposed, to the intermediate temporary substrate 590, and is formed above the passivation layer 550 and the contact electrode 560. Due to the shape of the temporary bonding layer 580 that encloses the contact electrode 560, the contact electrode 560 is interposed between the temporary bonding layer 580 and the first ohmic electrode 530 and thus is not exposed.

The temporary bonding layer 580 may include materials such as benzocyclobutene (BCB), SU-8 polymer, flowable oxides (FOx) such as spin-on-glass (SOG) and hydrogen silsesquioxane (HSQ), and alloys including low melting point metals (e.g., In, Sn, and Zn) and noble metals (e.g., Au, Ag, Cu, and Pd).

The intermediate temporary substrate 590 is bonded to the passivation layer 550 by the temporary bonding layer 580 to support the light-emitting part 520, the first ohmic electrode 530, the passivation layer 550, the contact electrode 560, and the bonding pad layer 570 to be described below, and it is preferable that the intermediate temporary substrate 590 is formed of a material that has a thermal expansion coefficient equal or similar to that of the initial growth substrate 510, and is simultaneously optically transparent, as long as the difference in thermal expansion coefficient does not exceed 2 ppm. The most preferable materials for the intermediate temporary substrate 590 that meet these requirements include sapphire, which is used for the initial growth substrate 510, or glass that has been adjusted to have a difference in thermal expansion coefficient of 2 ppm or lower from the initial growth substrate 510.

Meanwhile, in the present invention, the intermediate temporary substrate 590 functions as a final support substrate that supports the light-emitting part 520, the first ohmic electrode 530, the passivation layer 550, the contact electrode 560, and the bonding pad layer 570 to be described below after the epitaxial die 500 of the present invention is finally completed. At this time, it is preferable that an LLO sacrificial separation layer (not shown), which is a functional material that can be easily separated and removed by an LLO technique in the process of a third operation of a method (S50) of manufacturing the semiconductor light-emitting device, which will be described below, is formed between the intermediate temporary substrate 590 and the temporary bonding layer 580. The above-described LLO sacrificial separation layer (not shown) may be made of materials such as ZnO, ITO, IZO, IGO, IGZO, InGaN, InGaON, GaON, TiN, SiO2, SiNx, and the like.

The bonding pad layer 570 functions as a vertical chip die bonding pad, and is formed on a lower surface of the light-emitting part 520 to be electrically connected to the light-emitting part 520. At this time, the lower surface of the light-emitting part 520 has a nitrogen (N) polar surface, and the bonding pad layer 570 is electrically connected to the nitrogen (N) polar surface through an n-ohmic contact, is exposed to the outside, and functions as a negative electrode as well as an active reflector.

It is preferable that the bonding pad layer 570 basically includes three regions (not shown). A first region may include transparent electrically conductive materials (i.e., ITO, IZO, ZnO, IGZO, and TiN) with strong adhesion to the light-emitting part 520. A second region may include highly reflective materials (i.e., Al, Ag, AgCu, Rh, Pt, Ni, and Pd). A third region may include low melting point metals and noble metals such as gold (Au), silver (Ag), copper (Cu), and palladium (Pd), but the present invention is not limited thereto. In addition, the low melting point metals of the bonding pad layer 570 may be formed of metals such as In, Sn, Zn, and Pb alone or an alloy including these metals.

Furthermore, although not shown in the drawing, before forming the bonding pad layer 570 on the lower surface of the light-emitting part 520, a surface texture pattern with a predetermined shape or an irregular shape may be formed on a lower surface of the second semiconductor region 522 to extract as much light generated in the active region 523 into the air as possible.

Accordingly, in the epitaxial die 500 for a semiconductor light-emitting device according to the fifth embodiment of the present invention, the contact electrode 560 serving as a positive electrode and the first ohmic electrode 530 are interposed between the temporary bonding layer 580 and the light-emitting part 520 and thus are not exposed, and only the bonding pad layer 570 functioning as a negative electrode is exposed to the outside.

Hereinafter, with reference to the accompanying drawings, a semiconductor light-emitting device 50 according to the fifth embodiment of the present invention will be described in detail.

The semiconductor light-emitting device of the present invention may be formed as a COB in which individual chips or epitaxial die units are directly transferred and connected to a substrate (such as a semiconductor wafer, a PCB, or TFT glass) on which circuit wiring and driving element regions are completed, a POB in which package units (including 1, 2, 5, 9, 56, . . . , and n2 chips or epitaxial die units) manufactured using a fan-out package process known in conventional memory semiconductor technology are directly transferred and connected to a substrate on which circuit wiring and driving element regions (such as a semiconductor wafer, a PCB, or TFT glass) are completed, or an interposer using an intermediate temporary substrate 590 on which circuit wiring and driving element regions are not completed, but is not limited thereto, and will be described herein as being formed as the COB type for convenience of description.

FIG. 26 illustrates an overall view of the semiconductor light-emitting device according to the fifth embodiment of the present invention.

As shown in FIG. 26, the semiconductor light-emitting device 50 according to the fifth embodiment of the present invention includes a substrate part 51, the epitaxial die 500, a bonding layer 52, an extension electrode 53, a mold part 54, and a black matrix 55.

The substrate part 51 supports the epitaxial die 500 that is bonded thereto, and a first electrode pad 51a and a second electrode pad 51b are each formed on an upper surface of the substrate part 51. The substrate part 51 may refer to a semiconductor wafer, a PCB, TFT glass, an interposer, or the like, but the present invention is not limited thereto.

Further, the first electrode pad 51a may refer to an individual negative electrode, and the second electrode pad 51b may refer to a common positive electrode. For example, after three epitaxial dies 500 emitting blue, green, and red light are respectively placed on three individual negative electrodes and bonded to form a single pixel, each of the epitaxial dies 500 may be electrically connected to the common positive electrode.

The epitaxial die 500 is placed on the first electrode pad 51a of the substrate part 51 such that a bonding pad layer 570 comes into contact with the first electrode pad 51a, and includes a light-emitting part 520, a first ohmic electrode 530, a passivation layer 550, a contact electrode 560, and a bonding pad layer 570.

Here, the light-emitting part 520, the first ohmic electrode 530, the passivation layer 550, the contact electrode 560, and the bonding pad layer 570 are the same as those of the epitaxial die 500 for the semiconductor light-emitting device according to the fifth embodiment of the present invention described above, and thus redundant descriptions will be omitted.

Meanwhile, after the intermediate temporary substrate 590 is separated, the temporary bonding layer 580 is etched and removed, thereby exposing the contact electrode 560.

The bonding layer 52 electrically connects the first electrode pad 51a of the substrate part 51 and the bonding pad layer 570 of the epitaxial die 500 by bonding them together, and may include low melting point metals and noble metals such as gold (Au), silver (Ag), copper (Cu), and palladium (Pd) similar to or the same as the bonding pad layer 570 of the epitaxial die 500, but the present invention is not limited thereto.

The extension electrode 53 electrically connects the second electrode pad 51b of the substrate part 51 to the contact electrode 560 of the epitaxial die 500, and is formed to extend vertically from an upper portion of the second electrode pad 51b to above the mold part 54 through a through hole H of the mold part 54, which will be described below, and then extend horizontally by being bent toward the contact electrode 560 to come into contact with and be electrically connected to the contact electrode 560.

The extension electrode 53 may be formed of optically transparent and electrically conductive ceramics such as ITO, TiN, carbon nanotubes (CNT), and silver nanowires (Ag nanowires), or low melting point metals and noble metals such as gold (Au), silver (Ag), copper (Cu), and palladium (Pd) similar to or the same as the above-described materials of the bonding layer 52, but the present invention is not limited thereto.

The mold part 54 surrounds and supports the epitaxial die 500 and the extension electrode 53, which are disposed to form a vertical structure, and is formed so that an upper surface of the extension electrode 53 is exposed. In the mold part 54, the through hole H is formed above the second electrode pad 51b, and the extension electrode 53 is electrically connected to the second electrode pad 51b and the contact electrode 560 through the through hole H.

Meanwhile, laser drilling may be used to form the through holes H, and in this case, the mold part 54 may be made of materials that enable LDS or LDI.

The black matrix (BM) 55 covers the exposed upper surfaces of the extension electrode 53 and the mold part 54, and may be formed using photolithography and spin coating processes, but the present invention is not limited thereto.

In addition, the black matrix 55 may be formed of a metal thin film or a carbon-based organic material with an optical density of 3.5 or higher, but the present invention is not limited thereto. More specifically, representative examples thereof include a chromium (Cr) monolayer film, a chromium (Cr)/chromium oxide (CrOx) bilayer film, manganese dioxide (MnO2), an organic black matrix, graphite, and a pigment dispersion composition (prepared by blending a block copolymer resin with pigment-affinity groups such as amino, hydroxyl, and carboxyl groups, with carbon black as a medium, and mixing the blend with a solvent and a dispersing agent).

Hereinafter, with reference to the accompanying drawings, a method (S500) of manufacturing the epitaxial die for a semiconductor light-emitting device according to the fifth embodiment of the present invention will be described in detail.

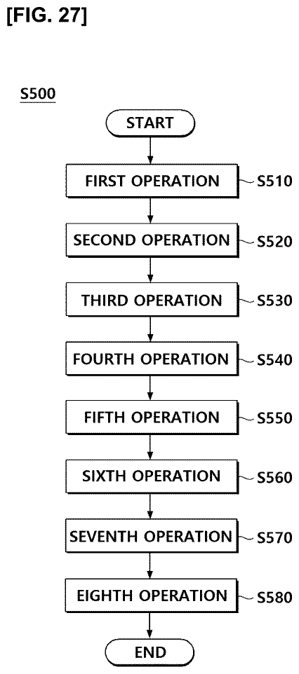

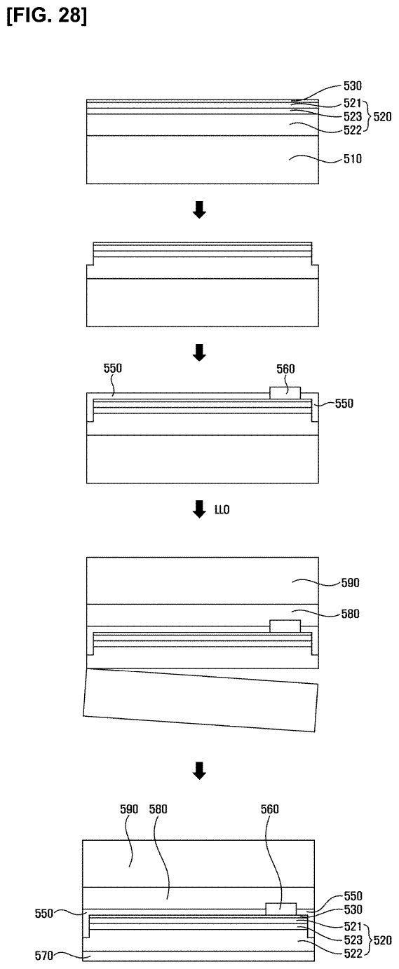

FIG. 27 is a flowchart of the method of manufacturing the epitaxial die for a semiconductor light-emitting device according to the fifth embodiment of the present invention, and FIG. 28 illustrates a process of manufacturing the epitaxial die for a semiconductor light-emitting device according to the fifth embodiment of the present invention.

As shown in FIGS. 27 and 28, the method (S500) of manufacturing the epitaxial die for a semiconductor light-emitting device according to the fifth embodiment of the present invention includes a first operation S510, a second operation S520, a third operation S530, a fourth operation S540, a fifth operation S550, a sixth operation S560, a seventh operation S570, and an eighth operation S580. However, it is of course possible that the order of the processes shown in FIGS. 27 and 28 can be changed.

The first operation S510 is an operation of preparing an initial growth substrate 510 and an intermediate temporary substrate 590. The initial growth substrate 510 is a substrate on which a light-emitting part 520 to be described below is epitaxially grown, and a sapphire initial growth substrate 510 may be used.

The intermediate temporary substrate 590 is bonded to a passivation layer 550 by a temporary bonding layer 580 to be described below and supports the light-emitting part 520, a first ohmic electrode 530, a passivation layer 550, a contact electrode 560, and a bonding pad layer 570 to be described below, and may include sapphire, which is used as the initial growth substrate 510, or glass that has been adjusted to have a difference in thermal expansion coefficient of 2 ppm or lower from the initial growth substrate 510.

Meanwhile, in the present invention, after the epitaxial die 500 of the present invention is finally completed, the intermediate temporary substrate 590 functions as a final support substrate that supports the light-emitting part 520, the first ohmic electrode 530, the passivation layer 550, the contact electrode 560, and the bonding pad layer 570.

The second operation S520 is an operation of forming the light-emitting part 520 on the initial growth substrate 510. That is, more specifically, the light-emitting part 520 includes a first semiconductor region 521 (e.g., a p-type semiconductor region), an active region 523 (e.g., MQWs), and a second semiconductor region 522 (e.g., an n-type semiconductor region), and in the second operation S520, the second semiconductor region 522, the active region 523, and the first semiconductor region 521 are epitaxially grown in this order on the initial growth substrate 510.

The third operation S530 is an operation of forming the first ohmic electrode 530 that is electrically connected to the first semiconductor region 521 by covering so as to come into surface contact with an upper surface of the first semiconductor region 521 of the light-emitting part 520. At this time, heat treatment is selectively performed at a high temperature of 300° C. or higher so that the first semiconductor region 521 forms a p-ohmic contact with the first ohmic electrode 530.

The fourth operation S540 is an operation of etching both sides of each of the light-emitting part 520 and the first ohmic electrode 530 to a predetermined depth and forming the passivation layer 550, which covers the first ohmic electrode 530 from the etched portions on both sides of the light-emitting part 520.

The fifth operation S550 is an operation of etching a portion of the passivation layer 550 to expose the first ohmic electrode 530 and forming the contact electrode 560 to come into contact with the exposed first ohmic electrode 530.

The sixth operation S560 is an operation of bonding the intermediate temporary substrate 590 and the passivation layer 550, in which the contact electrode 560 is exposed, through the temporary bonding layer 580. Due to the shape of the temporary bonding layer 580 that encloses the contact electrode 560, the contact electrode 560 is interposed between the temporary bonding layer 580 and the first ohmic electrode 530 and thus is not exposed.

The seventh operation S570 is an operation of separating the initial growth substrate 510. At this time, in the seventh operation S570, the initial growth substrate 510 may be separated from the light-emitting part 520, specifically from the second semiconductor region 522 using an LLO technique to expose an upper surface of the second semiconductor region 522. Here, the LLO technique refers to a technique of separating the initial growth substrate 510 from the epitaxially grown layers by irradiating a rear surface of the transparent growth substrate 510 with a UV laser beam having a uniform light output and beam profile, and a single wavelength.

The eighth operation S580 is an operation of forming the bonding pad layer 570 that is formed on a lower surface of the light-emitting part 520, is electrically connected to the light-emitting part 520, and functions as a vertical chip bonding pad. At this time, the lower surface of the light-emitting part 520 has a nitrogen (N) polar surface, and the bonding pad layer 570 is electrically connected to the nitrogen (N) polar surface through an n-ohmic contact, is exposed to the outside, and functions as a negative electrode. Meanwhile, in the eighth operation S580, the bonding pad layer 570 is heat treated at a high temperature of 300° C. or higher to form an n-ohmic contact with the lower surface of the light-emitting part 520.

After the basic structure of the epitaxial die 500 is formed through the above-described first operation S510 to eighth operation S580, processes such as grinding, dicing, probing, and sorting are performed.

Hereinafter, with reference to the accompanying drawings, a method (S50) of manufacturing the semiconductor light-emitting device according to the fifth embodiment of the present invention will be described in detail.

The semiconductor light-emitting device 50 of the present invention may be formed as a COB in which individual chips or epitaxial die units are directly transferred and connected to a substrate (such as a semiconductor wafer, a PCB, or TFT glass) on which circuit wiring and driving element regions are completed, a POB in which package units (including 1, 2, 5, 9, 56, . . . , and n2 chips or epitaxial die units) manufactured using a fan-out package process known in conventional memory semiconductor technology are directly transferred and connected to a substrate on which circuit wiring and driving element regions (such as a semiconductor wafer, a PCB, or TFT glass) are completed, or an interposer using an intermediate temporary substrate 590 on which circuit wiring and driving element regions are not completed, but is not limited thereto, and will be described herein as being formed as the COB type for convenience of description.

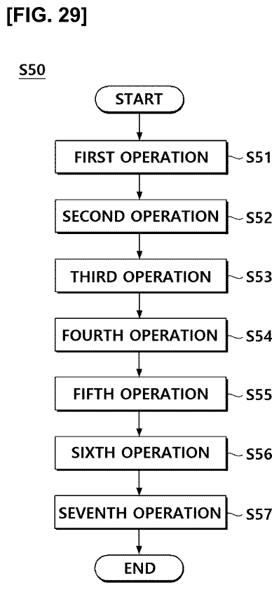

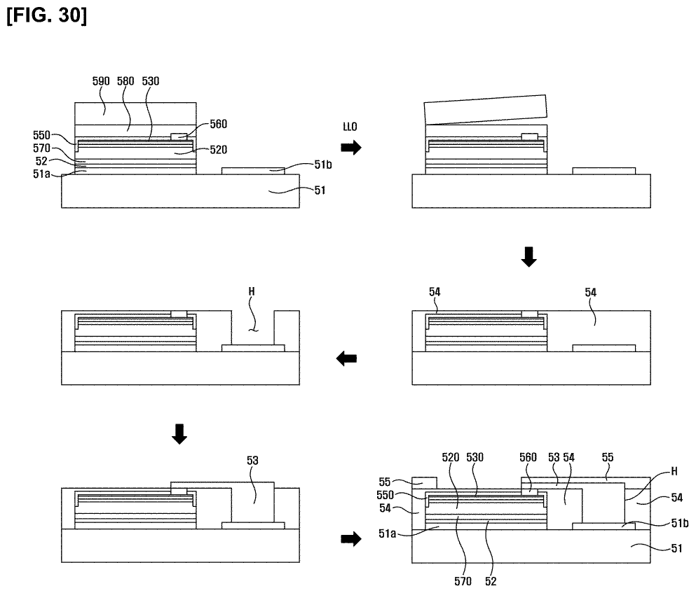

FIG. 29 is a flowchart of the method of manufacturing the semiconductor light-emitting device according to the fifth embodiment of the present invention, and FIG. 30 illustrates a process of manufacturing the semiconductor light-emitting device according to the fifth embodiment of the present invention.

As shown in FIGS. 29 and 30, the method (S50) of manufacturing the semiconductor light-emitting device according to the fifth embodiment of the present invention includes a first operation S51, a second operation S52, a third operation S53, a fourth operation S54, a fifth operation S55, a sixth operation S56, and a seventh operation S57. However, it is of course possible that the order of the processes shown in FIGS. 29 and 30 can be changed.

The first operation S51 is an operation of preparing the epitaxial die 500 for a semiconductor light-emitting device according to the fifth embodiment of the present invention and a substrate part 51 on which a first electrode pad 51a and a second electrode pad 51b are each formed. The substrate part 51 may refer to a semiconductor wafer, a PCB, TFT glass, an interposer, or the like, but the present invention is not limited thereto.

The second operation S52 is an operation of placing the epitaxial die 500 on the first electrode pad 51a, which is an individual negative electrode, and electrically connecting the first electrode pad 51a and the bonding pad layer 570 by bonding them through a bonding layer 52. At this time, the placement and bonding of the epitaxial die 500 can be accomplished through typical chip die transfer processes such as pick-and-place, roll-to-roll (R2R), and stamps (made from materials such as polydimethylsiloxane (PDMS), silicon (Si), quartz, and glass), which are commonly known tools used in representative processes of massive transfer.

Meanwhile, when it is necessary to achieve objectives such as (1) high precision placement of an epitaxial die 500, (2) an epitaxial die 500 with a ultra-small size of less than 50 μm×50 μm, and (3) an epitaxial die 500 having a self-assembly structure, additional masking media (such as a photoresist, ceramics (like glass, quartz, and alumina), or an invar FMM) or processes may be employed before the placement and bonding of the epitaxial die 500.

The third operation S53 is an operation of separating the intermediate temporary substrate 590 of the epitaxial die 500 and etching the temporary bonding layer 580 to expose the contact electrode 560. At this time, the third operation S53 may separate the intermediate temporary substrate 590 from the temporary bonding layer 580 using an LLO technique. Here, the LLO technique refers to a technique of separating the intermediate temporary substrate 590 from the temporary bonding layer 580 by irradiating a rear surface of the intermediate temporary substrate 590 with a UV laser beam having a uniform light output and beam profile, and a single wavelength.

The fourth operation S54 is an operation of forming a mold part 54 surrounding the epitaxial die 500 so that the contact electrode 560 is exposed. At this time, the mold part 54 may be made of materials that enable LDS or LDI to allow laser drilling in the fifth operation S55 to be described below.

The fifth operation S55 is an operation of etching the mold part 54 to expose the second electrode pad 51b. That is, in the fifth operation S55, a through hole H is formed above the second electrode pad 51b by etching the mold part 54 above the second electrode pad 51b using laser drilling.

The sixth operation S56 is an operation of forming an extension electrode 53 that electrically connects the second electrode pad 51b and the exposed contact electrode 560. That is, the extension electrode 53 is formed to extend vertically from an upper portion of the second electrode pad 51b to above the mold part 54 through the through hole H, and then extend horizontally by being bent toward the contact electrode 560 to come into contact with and be electrically connected to the contact electrode 560.

The seventh operation S57 is an operation of forming a black matrix 55 that covers the extension electrode 53 and the mold part 54. The black matrix 55 may be formed using photolithography and spin coating processes, but the present invention is not limited thereto.

Although all the components constituting the embodiments of the present invention have been described as being combined or combined to operate as one, the present invention is not necessarily limited to the embodiments. That is, one or more of all the components may be combined to operate as one within the scope of the present invention.

Further, since the terms, such as “comprising”, “including”, or “having” may mean that the corresponding component can be included unless otherwise stated, it should be construed that another component is not excluded but may be further included. Unless defined otherwise, all terms used herein, including technical or scientific terms, have the same meanings as those generally understood by those skilled in the art to which the present invention pertains. Commonly used terms, such as terms defined in dictionaries, should be interpreted as being consistent with the contextual meaning of the related art and are not interpreted in an ideal or excessively formal meaning unless explicitly defined herein.

In addition, the above description is merely an exemplary description of the technical spirit of the present invention, and the present invention may be subjected to various modifications and variations made by those skilled in the art to which the present invention pertains without departing from the essential features of the present invention.

Accordingly, the embodiments disclosed in the present invention are not provided to limit the technical spirit of the embodiments of the present invention but are provided to describe the present invention, and the scope of the technical spirit of the present invention is not limited by the embodiments. The scope of protection of the present invention should be construed by the attached claims, and all the technical ideas within the equivalent range fall within the scope of the present invention.

1. An epitaxial die for a semiconductor light-emitting device, wherein the epitaxial die is formed by separating into die units, and functions as a pixel after being individually transferred to a substrate part, comprising:
a growth substrate;
a light-emitting part formed on the growth substrate, having both side portions etched to a predetermined depth, and configured to generate light;
a first ohmic electrode formed on the light-emitting part and electrically connected to the light-emitting part;
a second ohmic electrode formed on the etched portions on both side of the light-emitting part and electrically connected to the light-emitting part;
a passivation layer formed from an etched portion on one side of the light-emitting part through the second ohmic electrode to cover a portion of one side of the first ohmic electrode, and from an etched portion on the other side of the light-emitting part through the second ohmic electrode to cover a portion of the other side of the first ohmic electrode, and formed horizontally so that upper surfaces have the same height; and
a bonding pad layer formed on the first ohmic electrode and the passivation layer to be electrically connected to the first ohmic electrode and functioning as a vertical chip bonding pad and exposed to the outside,
wherein the second ohmic electrode is interposed between the passivation layer and the light-emitting part and is not exposed to the outside before the epitaxial die is transferred to the substrate part,
wherein the growth substrate is optically transparent, and it is possible to determine optical defects of the epitaxial die before the epitaxial die is transferred to the substrate part.

2-20. (canceled)

21. The epitaxial die of claim 1, wherein the light-emitting part includes:
a first semiconductor region having first conductivity;
a second semiconductor region having second conductivity that is different from the first conductivity; and
an active region interposed between the first semiconductor region and the second semiconductor region and configured to generate light using recombination of electrons and holes.

22. The epitaxial die of claim 1, wherein the etched portion of the light-emitting part has a gallium (Ga) polar surface and is electrically connected to the second ohmic electrode by making a negative ohmic contact (n-ohmic contact).

23. An epitaxial die for a semiconductor light-emitting device, wherein the epitaxial die is formed by separating into die units, and is formed as a semi-finished product in which only one of the two electrodes is exposed to the outside, and functions as a pixel after being individually transferred to a substrate part, comprising:
a growth substrate;
a light-emitting part formed on the growth substrate, having one side etched to a predetermined depth, and configured to generate light;
a first ohmic electrode formed on the light-emitting part and electrically connected to the light-emitting part;
a second ohmic electrode formed on the etched portion on one side of the light-emitting part and electrically connected to the light-emitting part;
a first passivation layer covering the first ohmic electrode and the second ohmic electrode and partially open to expose a portion of the first ohmic electrode;
a contact electrode formed on the exposed first ohmic electrode and electrically connected to the first ohmic electrode;
a second passivation layer covering the first passivation layer and the contact electrode; and
a bonding pad layer formed on the second passivation layer to be electrically connected to the second ohmic electrode and functioning as a vertical chip bonding pad and exposed to the outside,
wherein the contact electrode includes a base part and an extension part that is formed to extend from an end portion of the base part to the other side of the light-emitting part,
wherein the extension part is formed by partially bending the end in a direction opposite to the bonding pad layer,
wherein the extension part is placed between the first passivation layer and the second passivation layer, and is not exposed to the outside before the epitaxial die is transferred to the substrate part and is not electrically connected to other electrodes,
wherein the growth substrate is optically transparent, and it is possible to determine optical defects of the epitaxial die before the epitaxial die is transferred to the substrate part.

24. The epitaxial die of claim 23, wherein the first passivation layer covers one side of the first ohmic electrode from the etched portion on one side of the light-emitting part through the second ohmic electrode, and covers the other side of the first ohmic electrode from the other side of the light-emitting part so that exposing a part of the first ohmic electrode.

25. The epitaxial die of claim 23, wherein a first through hole is formed in the first passivation layer above the second ohmic electrode to expose the second ohmic electrode, and a second through hole in communication with the first through hole is formed in the second passivation layer, and the bonding pad layer is electrically connected to the second ohmic electrode through the first through hole and the second through hole.

26. The epitaxial die of claim 23, wherein the light-emitting part includes:
a first semiconductor region having first conductivity;
a second semiconductor region having second conductivity that is different from the first conductivity; and
an active region interposed between the first semiconductor region and the second semiconductor region and configured to generate light using recombination of electrons and holes.

27. The epitaxial die of claim 23, wherein the etched portion of the light-emitting part has a gallium (Ga) polar surface and is electrically connected to the second ohmic electrode by making a negative ohmic contact (n-ohmic contact).
